(19) United States
(12) Patent Application Publication
(10) Pub. No.: US 2024/0397739 A1
(43) Pub. Date: Nov. 28, 2024

(54) LIGHT-EMITTING DEVICE AND METHOD FOR MANUFACTURING THE SAME, AND DISPLAY PANEL

(71) Applicant: BOE TECHNOLOGY GROUP CO., LTD., Beijing (CN)

(72) Inventors: Yang LIU, Beijing (CN); Dan WANG, Beijing (CN); Lei CHEN, Beijing (CN)

(73) Assignee: BOE TECHNOLOGY GROUP CO., LTD., Beijing (CN)

(21) Appl. No.: 18/694,414

(22) PCT Filed: Aug. 28, 2023
(86) PCT No.: PCT/CN2023/115302

§ 371 Date: Mar. 22, 2024

(30) Foreign Application Priority Data
Aug. 30, 2022 (CN) 202211050994.9

(51) Int. Cl. H10K 50/13; H10K 59/35; H10K 71/16

(52) U.S. Cl. CPC H10K 50/13; H10K 71/166; H10K 59/353

(57) ABSTRACT

A light-emitting device comprises a first electrode, at least two light-emitting units and a second electrode which are sequentially stacked in a first direction. The at least two light-emitting units comprise a first light-emitting unit and a second light-emitting unit, the second light-emitting unit being located between the first light-emitting unit and the second electrode. At least one light-emitting unit comprises a light-emitting layer and an exciton blocking layer located on the side of the light-emitting layer close to the first electrode; the exciton blocking layer comprises a first sub-layer and a second sub-layer which are stacked in the first direction; the first sub-layer is located between the second sub-layer and the light-emitting layer; and in the first direction, the thickness of the first sub-layer is smaller than that of the second sub-layer, and the highest occupied molecular orbital energy level of the first sub-layer is higher than the highest occupied molecular orbital energy level of the second sub-layer. The light-emitting device provided by the present disclosure can enable exciton recombination regions of the light-emitting layer corresponding to each light-emitting unit to get close as much as possible, thereby improving light-emitting efficiency of the light-emitting device.

### CROSS-REFERENCE TO RELATED APPLICATIONS

This application is a national phase entry under 35 USC 371 of International Patent Application No. PCT/CN2023/115302, filed on Aug. 28, 2023, which claims priority to Chinese Patent Application No. 202211050994.9, filed on Aug. 30, 2022, which are incorporated herein by reference in their entirety.

### TECHNICAL FIELD

The present disclosure relates to the field of display technologies, and in particular, to a light-emitting device and a method for manufacturing the same, and a display panel.

### BACKGROUND

Organic light-emitting diodes (OLEDs) have attracted attention of enterprises and universities due to self-luminescence, high brightness, high contrast, fast response speed, wide viewing angle, simple structure, flexible display, and other advantages, and have gained rapid development.

Thus, a tandem OLED has emerged in the development of OLEDs. The tandem OLED has advantages of high brightness. However, the tandem OLED in the related art has a problem of inconsistent light extraction efficiency between two light-emitting units.

### SUMMARY

In an aspect, a light-emitting device is provided. The light-emitting device includes a first electrode, at least two light-emitting units and a second electrode sequentially stacked in a first direction. The at least two light-emitting units include a first light-emitting unit and a second light-emitting unit, and the second light-emitting unit is located between the first light-emitting unit and the second electrode. At least one light-emitting unit of the at least two light-emitting units includes a light-emitting layer and an exciton blocking layer located on a side of the light-emitting layer proximate to the first electrode. The exciton blocking layer includes a first sub-layer and a second sub-layer stacked on each other in the first direction, and the first sub-layer is located between the second sub-layer and the light-emitting layer. In the first direction, a thickness of the first sub-layer is less than a thickness of the second sub-layer, and a highest occupied molecular orbital energy level of the first sub-layer is higher than a highest occupied molecular orbital energy level of the second sub-layer.

In some embodiments, the thickness of the second sub-layer is at most 6 times the thickness of the first sub-layer.

In some embodiments, an absolute value of a difference between the highest occupied molecular orbital energy level of the first sub-layer and the highest occupied molecular orbital energy level of the second sub-layer is less than 1 eV.

In some embodiments, a hole mobility of the first sub-layer is less than a hole mobility of the second sub-layer.

In some embodiments, the hole mobility of the second sub-layer is at most 100 times the hole mobility of the first sub-layer.

In some embodiments, the light-emitting layer includes a first host material and a luminescent material, and a ratio of the luminescent material to the first host material is in a range of 4% to 15%, inclusive.

In some embodiments, the first light-emitting unit includes a first light-emitting layer, the second light-emitting unit includes a second light-emitting layer, and both the first light-emitting unit and the second light-emitting unit include exciton blocking layers.

In some embodiments, a ratio of a luminescent material of the second light-emitting layer to a first host material of the second light-emitting layer is greater than a ratio of a luminescent material of the first light-emitting layer to a first host material of the first light-emitting layer.

In some embodiments, a ratio of a luminescent material of the second light-emitting layer to a first host material of the second light-emitting layer is at most 3 times a ratio of a luminescent material of the first light-emitting layer to a first host material of the first light-emitting layer.

In some embodiments, a hole mobility of a first sub-layer of an exciton blocking layer of the first light-emitting unit is less than or equal to a hole mobility of a first sub-layer of an exciton blocking layer of the second light-emitting unit.

In some embodiments, the hole mobility of the first sub-layer of the exciton blocking layer of the second light-emitting unit is at most 100 times the hole mobility of the first sub-layer of the exciton blocking layer of the first light-emitting unit.

In some embodiments, the light-emitting device further includes a charge generation layer, and the charge generation layer is located between the first light-emitting unit and the second light-emitting unit.

In some embodiments, the charge generation layer includes an N-type charge generation sub-layer and a P-type charge generation sub-layer stacked in the first direction, and the P-type charge generation sub-layer is located on a side of the N-type charge generation sub-layer away from the first electrode. The P-type charge generation sub-layer includes a second host material and a P-type doped material, and a ratio of the P-type doped material to the second host material is in a range of 1% to 6%, inclusive.

In some embodiments, the first light-emitting unit includes an exciton blocking layer. The first light-emitting unit further includes a hole injection layer, and the hole injection layer is located on a side of a second sub-layer in the first light-emitting unit proximate to the first electrode. The hole injection layer includes a third host material and a P-type doped material, and a ratio of the P-type doped material to the third host material is in a range of 1% to 6%, inclusive.

In some embodiments, the ratio of the P-type doped material in the P-type charge generation sub-layer to the second host material is greater than the ratio of the P-type doped material in the hole injection layer to the third host material.

In some embodiments, a difference between the ratio of the P-type doped material in the P-type charge generation sub-layer to the second host material and the ratio of the P-type doped material in the hole injection layer to the third host material is in a range of 0.8% to 5%, inclusive.

In another aspect, a display panel is provided. The display panel includes a pixel defining layer and a plurality of light-emitting devices. The pixel defining layer is provided with a plurality of light-emitting openings therein. The plurality of light-emitting devices cover the plurality of light-emitting openings, respectively, and at least one light-emitting device is the light-emitting device as described above.

In yet another aspect, a method for manufacturing a light-emitting device is provided. The method for manufacturing the light-emitting device includes: forming a first electrode; forming at least two light-emitting units on the first electrode, at least one light-emitting unit including a light-emitting layer and an exciton blocking layer located on a side of the light-emitting layer proximate to the first electrode, and the exciton blocking layer including a first sub-layer and a second sub-layer stacked on each other in a first direction; and forming a second electrode on the at least two light-emitting units.

In some embodiments, forming a light-emitting unit on the first electrode includes: using an open mask to evaporate a first exciton blocking material on the first electrode to form a second sub-layer; using the open mask to evaporate a second exciton blocking material on the second sub-layer to form a first sub-layer, the first sub-layer and the second sub-layer together constituting an exciton blocking material layer; and using a fine metal mask to form a light-emitting layer covering a light-emitting opening, the light-emitting layer being located on the first sub-layer.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a light-emitting device, in accordance with some embodiments;

FIG. 2 is a perspective view of a display panel, in accordance with some embodiments;

FIG. 3 is a sectional view of the display panel in the embodiment in FIG. 2 taken along a line A-A′;

FIGS. 4 to 8 are each a structural diagram of arrangement of sub-pixels in a display panel, in accordance with some embodiments;

FIG. 9 is a sectional view of a display panel, in accordance with some embodiments;

FIG. 10 is an enlarged view of an area F in FIG. 3 in some embodiments;

FIG. 11 is an enlarged view of an area F in FIG. 3 in some embodiments;

FIG. 12 is a diagram showing a molecular structural formula of a first material in a light-emitting device, in accordance with some embodiments;

FIG. 13 is a diagram showing a molecular structural formula of a second material in a light-emitting device, in accordance with some embodiments;

FIG. 14 is a diagram showing a molecular structural formula of a third material in a light-emitting device, in accordance with some embodiments;

FIG. 15 is a diagram showing a molecular structural formula of a fourth material in a light-emitting device, in accordance with some embodiments;

FIG. 16 is a diagram showing a molecular general formula of first to fourth materials in a light-emitting device, in accordance with some embodiments;

FIG. 17 is a flow diagram of a method for manufacturing a light-emitting device, in accordance with some embodiments; and

FIG. 18 is a flow diagram of a method for manufacturing a light-emitting device, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas are enlarged for clarity. Variations in shapes relative to the accompanying drawings due to, for example, manufacturing technologies and/or tolerances may be envisaged. Therefore, the exemplary embodiments should not be construed to be limited to the shapes of areas shown herein, but to include deviations in the shapes due to, for example, manufacturing. For example, an etched area shown in a rectangular shape generally has a feature of being curved. Therefore, the areas shown in the accompanying drawings are schematic in nature, and their shapes are not intended to show actual shapes of the areas in an apparatus, and are not intended to limit the scope of the exemplary embodiments.

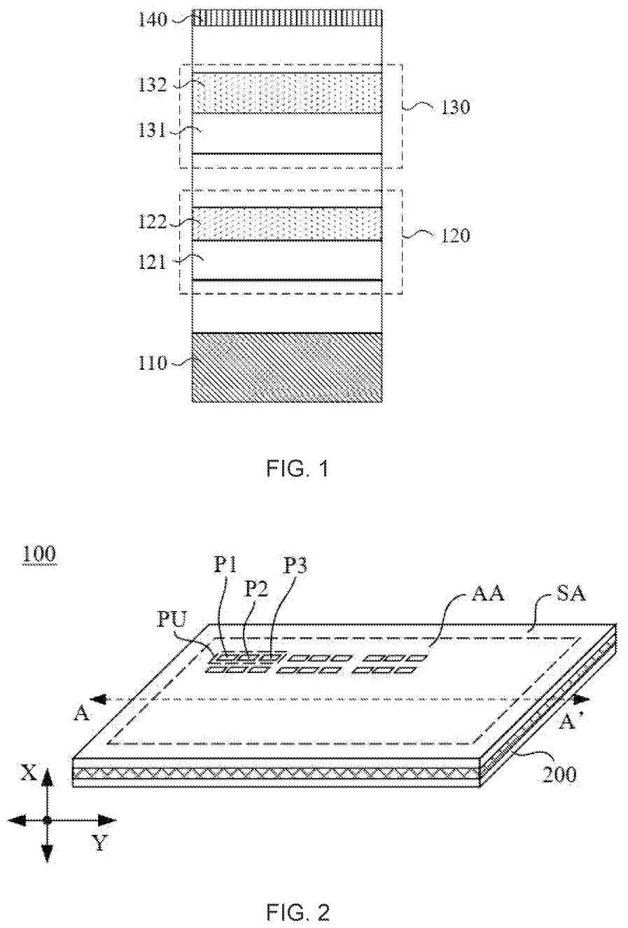

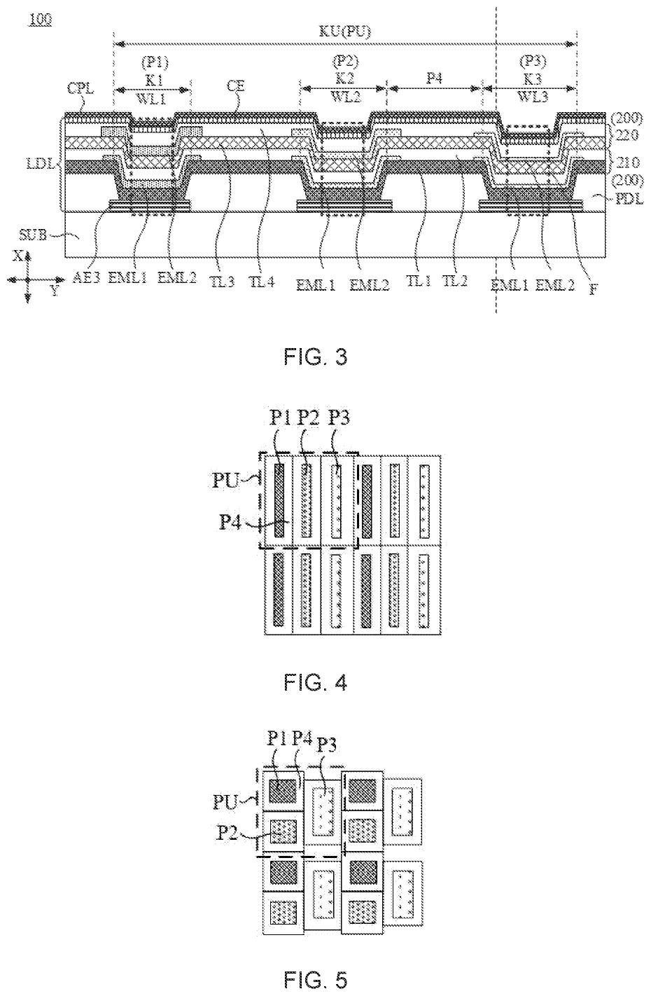

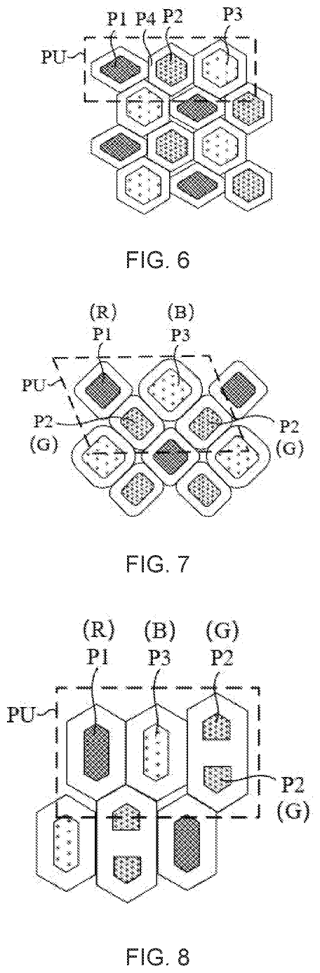

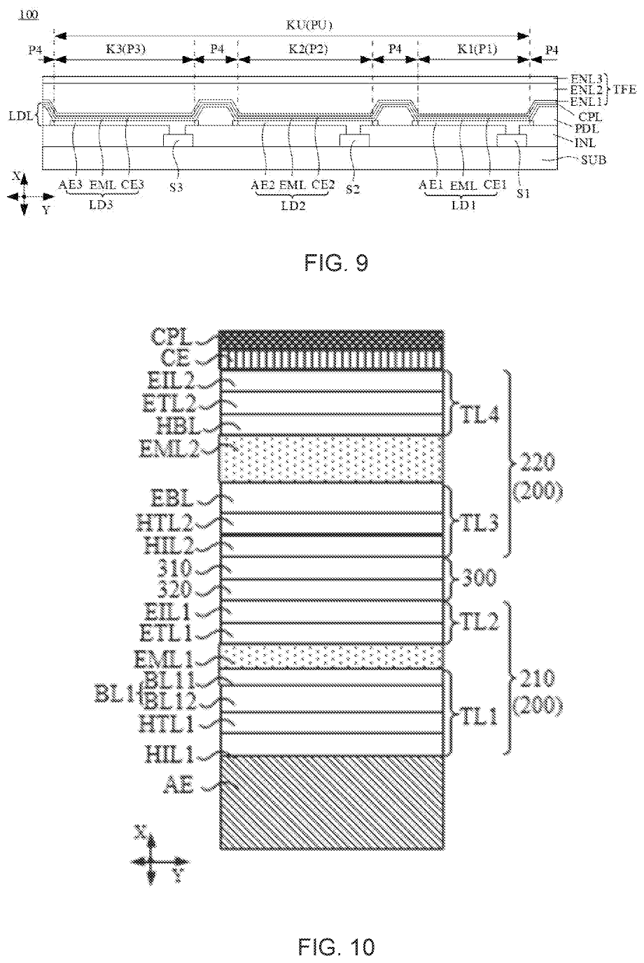

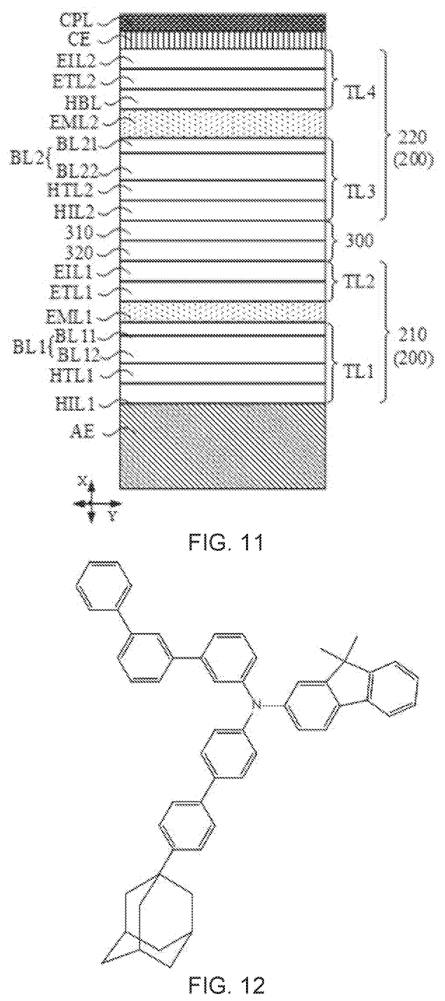

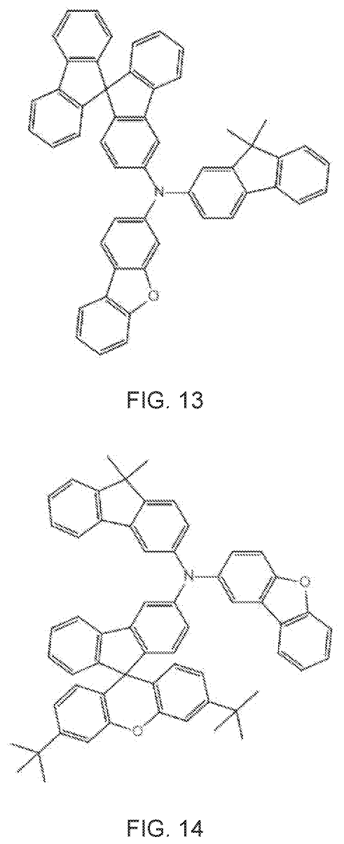

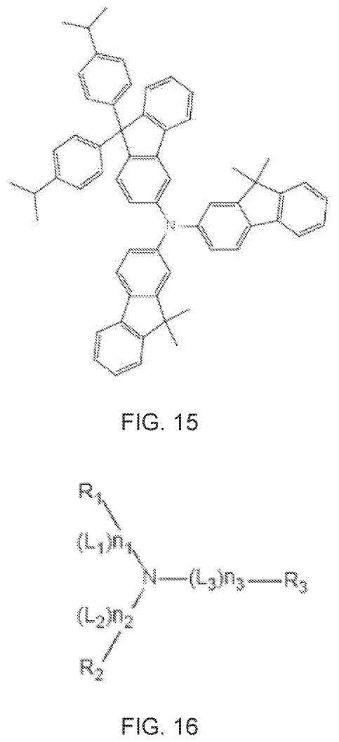

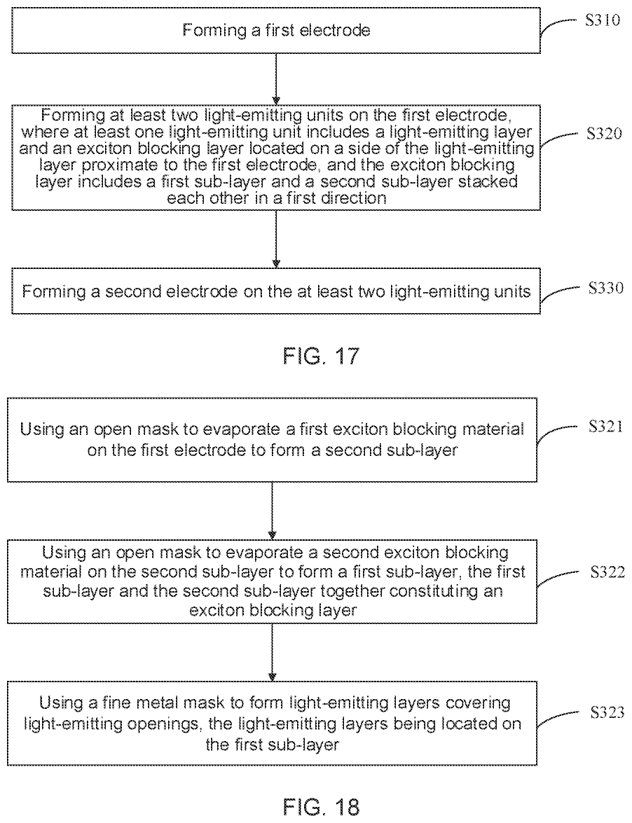

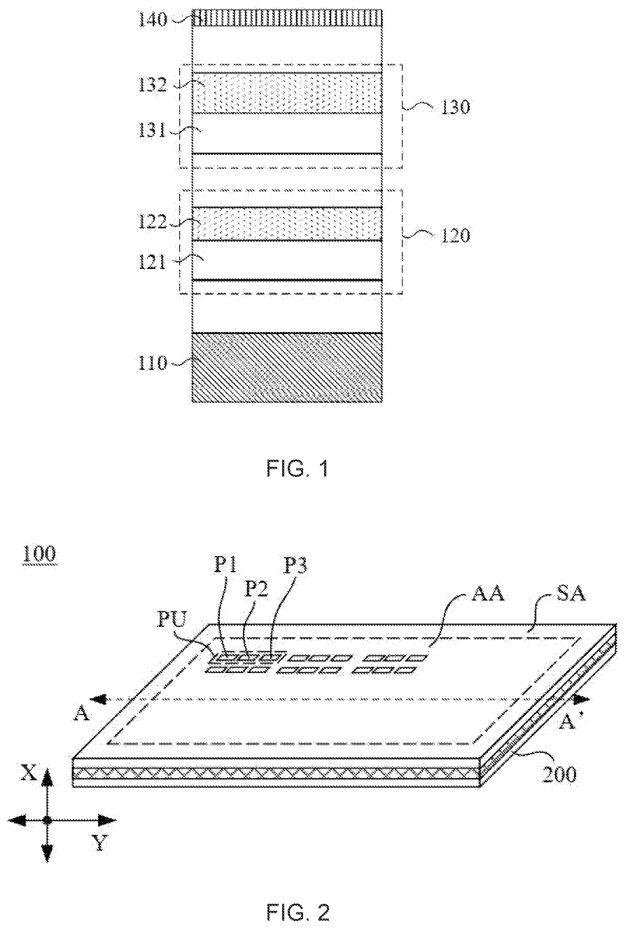

With development of tandem OLEDs, requirements for the luminous efficiency of the tandem OLEDs are gradually increasing. As shown in FIG. 1, a tandem OLED device generally includes a first electrode 110, a second electrode 140 and at least two light-emitting units (e.g., a first light-emitting unit 120 and a second light-emitting unit 130). The first light-emitting unit 120 and the second light-emitting unit 130 may be located between the first electrode 110 and the second electrode 140. The first electrode 110 may be used to provide holes, and the second electrode 140 may be used to provide electrons. The first light-emitting unit 120 includes a first light-emitting layer 122 and a first electron blocking layer 121, and the second light-emitting unit 130 includes a second light-emitting layer 132 and a second electron blocking layer 131. Each electron blocking layer blocks electrons so that the electrons stay in the adjacent light-emitting layer as much as possible, thereby improving the luminous efficiency of the light-emitting layer.

As shown in FIG. 1, in some embodiments, the first electron blocking layer 121 is provided on a side of the first light-emitting layer 122 proximate to the first electrode 110, and the second electron blocking layer 131 is provided on a side of the second light-emitting layer 132 proximate to the first electrode 110. When electrons are transported from the second electrode 140 to the first electrode 110, since the electrons are affected by the transmission barrier during transport, the amount of electrons remaining in the second light-emitting layer 132 is greater than the amount of electrons remaining in the first light-emitting layer 122.

In summary, the amount of electrons in the first light-emitting layer 122 is less than the amount of electrons in the second light-emitting layer 132. It can be seen that the amount of excitons generated by recombination of electrons and holes in the first light-emitting layer 122 is less than the amount of excitons generated by recombination of electrons and holes in the second light-emitting layer 132. Due to the difference between the amount of excitons in the first light-emitting layer 122 and the amount of excitons in the second light-emitting layer 132, an area of exciton recombination of the first light-emitting layer 122 and an area of exciton recombination of the second light-emitting layer 132 are different, so that the luminous efficiency of the first light-emitting layer 122 and the luminous efficiency of the second light-emitting layer 132 are also different. As a result, two light-emitting units in the light-emitting device have a poor light matching effect therebetween, ultimately resulting in low luminous efficiency of the overall light-emitting device.

In order to solve the problem of the low luminous efficiency of the overall light-emitting device, the present disclosure provides a light-emitting device and a method for manufacturing the same, and a display panel.

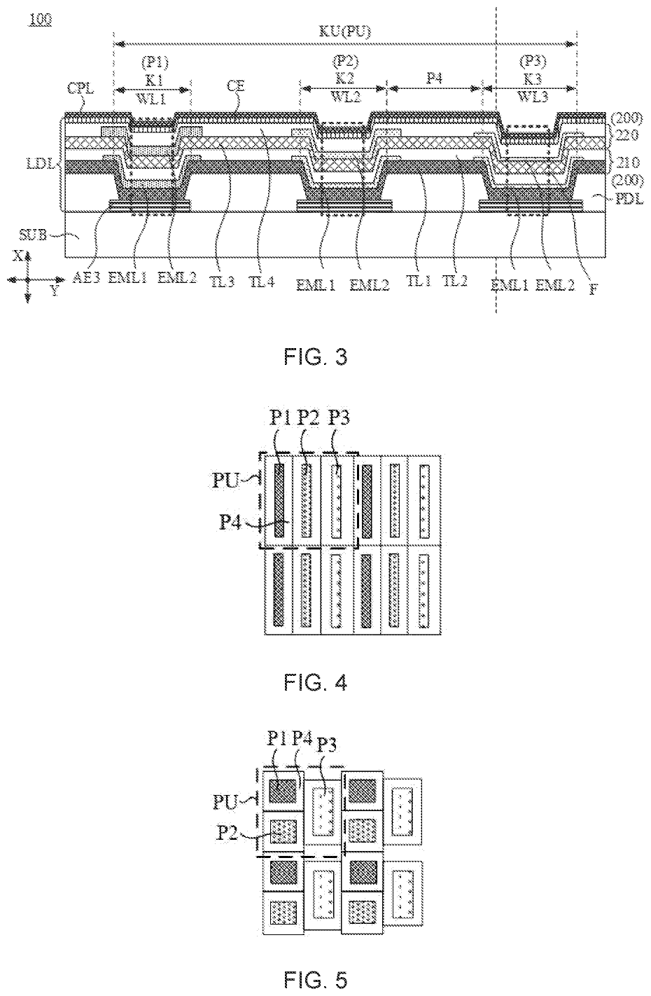

FIG. 2 is a perspective view of a display panel 100 in accordance with some embodiments. FIG. 3 is a sectional view of the display panel 100 in the embodiment in FIG. 2 taken along a line A-A′. As shown in FIG. 2, the display panel 100 includes a display area AA for displaying images and a non-display area SA that does not display images. The non-display area SA is located on at least one side (e.g., one side, or all sides, i.e., including upper and lower sides and left and right sides) of the display area AA. In some examples, the non-display area SA may enclose the display area AA, or may be located outside the display area AA in at least one direction. The display panel 100 may be, in a plan view, in a shape of a rectangle, a circle, an ellipse, a rhombus, a trapezoid, a square or any other shape depending to display requirements.

The display panel 100 may be applied to a display apparatus. For example, the display apparatus may be a small and medium sized electronic apparatus such as a tablet computer, a smart phone, a head-mounted display, an automobile navigation unit, a camera, a central information display (CID) provided in a vehicle, a wristwatch-type electronic apparatus or any other wearable device, a personal digital assistant (PDA), a portable multimedia player (PMP) and a game console, and a medium and large sized electronic apparatus such as a television, an external billboard, a monitor, a home appliance including a display screen, a personal computer and a laptop computer. The electronic apparatuses mentioned above may represent simple examples for being applied to a display apparatus. Moreover, it may be recognized by a person of ordinary skill in the art that the display apparatus may be any other electronic apparatus without departing from the spirit and scope of the present disclosure.

In combination with FIGS. 2, 3 and 9, some embodiments of the present disclosure provide a display panel 100. The display panel 100 includes a substrate SUB, a light-emitting device layer LDL, a light extraction layer CPL and an encapsulation layer TFE.

The substrate SUB includes a plurality of pixel unit areas PU that are repeatedly arranged. Each pixel unit area PU may include first sub-pixel area(s) P1, second sub-pixel area(s) P2 and third sub-pixel area(s) P3 that display different colors. For example, the first sub-pixel area P1 is configured to display red light, the second sub-pixel area P2 is configured to display green light, and the third sub-pixel area P3 is configured to display blue light.

In addition, the pixel unit area PU may further include a non-light-emitting area P4. The non-light-emitting area P4 may be located between the first sub-pixel area P1 and the second sub-pixel area P2, between the second sub-pixel area P2 and the third sub-pixel area P3, and between the third sub-pixel area P3 and the first sub-pixel area P1.

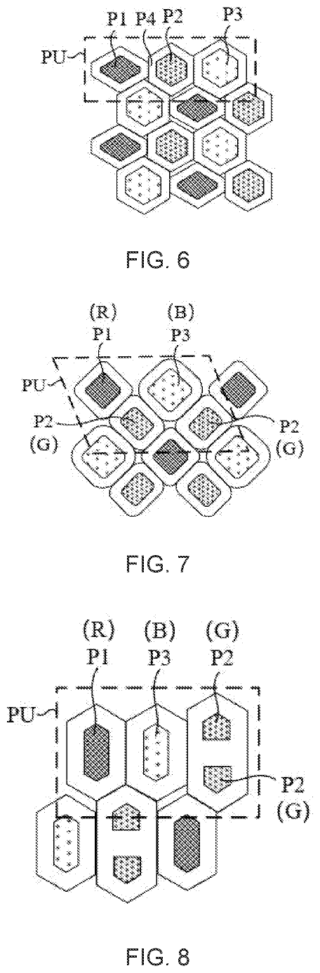

In some examples, as shown in FIGS. 4 to 6, a pixel unit area PU includes one first sub-pixel area P1, one second sub-pixel area P2 and one third sub-pixel area P3. The first sub-pixel area P1, the second sub-pixel area P2 and the third sub-pixel area P3 may be arranged spaced apart one another in a second direction Y and arranged as a repeating unit in the display area AA.

In some examples, as shown in FIGS. 7 and 8, a pixel unit area PU may include two sub-pixel areas for displaying the same color, and the two sub-pixel areas for displaying the same color may be disposed adjacently. For example, the pixel unit area PU includes one red sub-pixel area R, two green sub-pixel areas G and one blue sub-pixel area B, and the two green sub-pixel areas G in the pixel unit area PU may be disposed adjacently.

In some examples, a pixel unit area PU includes one first sub-pixel area P1, two second sub-pixel areas P2 and one third sub-pixel area P3. The first sub-pixel area P1, the two second sub-pixel areas P2 and the third sub-pixel area P3 may be arranged spaced apart one another in the second direction Y and arranged as a repeating unit in the display area AA. In this case, the non-light-emitting area P4 may further be located between the two second sub-pixel areas P2.

As shown in FIG. 3, in a pixel unit area PU and in the second direction (a direction parallel to the substrate SUB) Y, the first sub-pixel area P1 has a first width WL1, the second sub-pixel area P2 has a second width WL2, and the third sub-pixel area P3 has a third width WL3. The first width WL1, the second width WL2 and the third width WL3 may be different from one other.

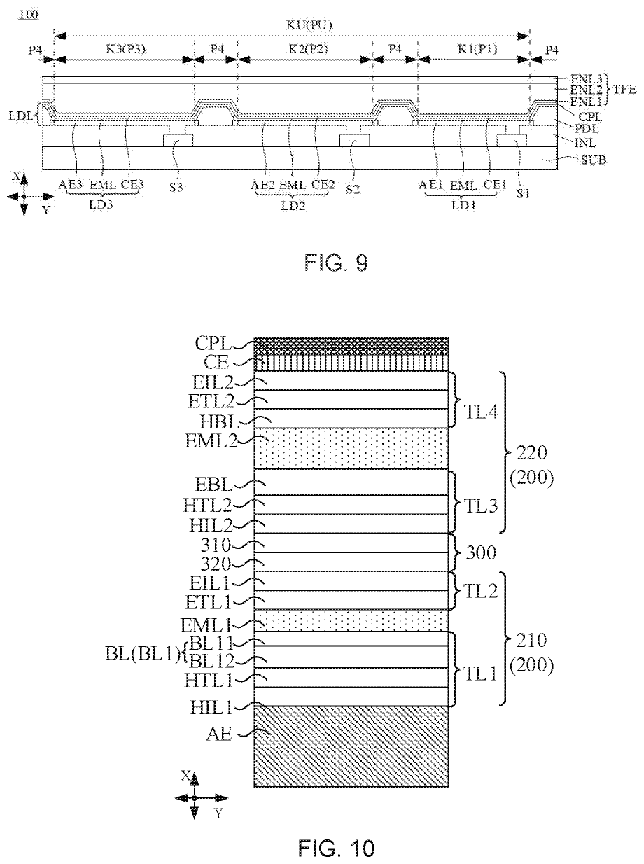

As shown in FIG. 9, the display panel 100 may include a plurality of pixel circuits located on the base substrate SUB. A pixel unit area PU may include a first pixel circuit S1, a second pixel circuit S2 and a third pixel circuit S3. For example, the first pixel circuit S1 is located in the first sub-pixel area P1, the second pixel circuit S2 is located in the second sub-pixel area P2, and the third pixel circuit S3 is located in the third sub-pixel area P3. As another example, thin film transistors in at least one of the first pixel circuit S1, the second pixel circuit S2, and the third pixel circuit S3 may be located in the non-light-emitting area P4.

The structure of the pixel circuit varies and may be provided according to actual needs. For example, the pixel circuit may include at least two transistors (denoted by T) and at least one capacitor (denoted by C). For example, the pixel circuit may have a “2T1C” structure, a “6T1C” structure, a “7T1C” structure, a “6T2C” structure, a “7T2C” structure, or the like.

Thin film transistors in at least one of the first pixel circuit S1, the second pixel circuit S2 and the third pixel circuit S3 may be thin film transistors including polysilicon or thin film transistors including oxide semiconductors. For example, in a case where the thin film transistors are the thin film transistors including oxide semiconductors, the thin film transistors each may have a top-gate thin film transistor structure. The thin film transistors may be connected to signal lines, and the signal lines include but are not limited to gate lines, data lines and power lines.

As shown in FIG. 9, the display panel 100 may include an insulating layer INL, which may be located on the first pixel circuit S1, the second pixel circuit S2 and the third pixel circuit S3. The insulating layer INL may have a flat surface. The insulating layer INL may be made from an organic layer. For example, the insulating layer INL may include acrylic resin, epoxy resin, imide resin or ester resin. The insulating layer INL may have through holes exposing electrodes of the first pixel circuit S1, the second pixel circuit S2 and the third pixel circuit S3, so as to achieve electrical connection.

In combination with FIGS. 3 and 9, the display panel 100 may include the light-emitting device layer LDL and a pixel defining layer PDL that are located above the base substrate SUB. The pixel defining layer PDL may be formed on the insulating layer INL and defines a plurality of light-emitting openings. For example, the pixel defining layer PDL includes a first light-emitting opening K1 located in the first sub-pixel area P1, a second light-emitting opening K2 located in the second sub-pixel area P2, and a third light-emitting opening K3 located in the third sub-pixel area P3. A plurality of light-emitting devices connected to the pixel circuits are formed in the light-emitting device layer LDL, and the plurality of light-emitting devices respectively cover the plurality of light-emitting openings. In a pixel unit area PU, the light-emitting devices include a first light-emitting device LD1, a second light-emitting device LD2 and a third light-emitting device LD3. For example, the first light-emitting device LD1 covers the first light-emitting opening K1, the second light-emitting device LD2 covers the second light-emitting opening K2, and the third light-emitting device LD3 covers the third light-emitting opening K3.

As shown in FIG. 3, in some embodiments, the plurality of light-emitting openings constitute at least one light-emitting opening unit KU. A light-emitting opening unit KU includes a first light-emitting opening K1, a second light-emitting opening K2, and a third light-emitting opening K3 that correspond to different colors.

A light-emitting opening unit KU corresponds to a pixel unit area PU, and the number of light-emitting openings in the light-emitting opening unit KU is equal to the number of sub-pixel areas in the pixel unit area. Multiple light-emitting openings in the light-emitting opening unit KU are in one-to-one correspondence to multiple sub-pixel areas in the pixel unit area PU.

It can be understood that a light-emitting opening unit KU may include one or more first light-emitting openings K1, one or more second light-emitting openings K2, and one or more third light-emitting openings K3.

The first light-emitting device LD1 may cover the first light-emitting opening K1, the second light-emitting device LD2 may cover the second light-emitting opening K2, and the third light-emitting device LD3 may cover the third light-emitting opening K3.

In some embodiments, the light-emitting device may include a first electrode, at least two light-emitting units 200 and a second electrode that are sequentially stacked in a first direction (i.e., a direction perpendicular to the substrate SUB) X.

In some examples, the display panel 100 may be a top-emission display panel 100. The first electrode is a reflective electrode that may reflect light, such as an anode. The second electrode is a transmissive electrode that may transmit light, such as a cathode. In this way, a microcavity structure is formed between the anode and the cathode.

In some other examples, the display panel 100 may be a bottom-emission display panel 100. The first electrode is a transmissive electrode that may transmit light, such as an anode. The second electrode CE is a reflective electrode that may reflect light, such as a cathode. In this way, a microcavity structure is formed between the anode and the cathode.

As shown in FIGS. 9 and 10, the first electrodes AE include a first electrode AE1 located in the first sub-pixel area P1, a first electrode AE2 located in the second sub-pixel area P2, and a first electrode AE3 located in the third sub-pixel area P3.

In some embodiments, the first electrode may include a material with a high work function, such as a material of a metal or combination of Ag, Mg, Al, Pt, Pd, Au, Ni, Nd, Ir or Cr, or may be made of a transparent conductive oxide material such as indium tin oxide (ITO), indium zinc oxide (IZO), or indium gallium zinc oxide (IGZO). A dimension of the first electrode in the first direction X may be in a range of 80 nm to 200 nm, inclusive.

In some examples, the display panel 100 is a top-emission display panel 100. The first electrode AE may include a laminated composite structure of transparent conductive oxide/metal/transparent conductive oxide. The material of the transparent conductive oxide is, for example, ITO or IZO, and the material of the metal is, for example, Au, Ag, Ni or Pt. For example, the anode has a structure of ITO/Ag/ITO. A dimension of the metal in the first direction X may be in a range of 80 nm to 100 nm, inclusive; and a dimension of the transparent conductive oxide in the first direction X may be in a range of 5 nm to 10 nm, inclusive. In addition, an average reflectivity of the first electrode for visible light may be in a range of 85% to 95%, inclusive.

In some examples, the display panel 100 is a bottom-emission display panel 100. The second electrode may include a transparent conductive oxide such as ITO, IZO or IGZO.

In some embodiments, the second electrode CE may include a metal material or an alloy material. The metal material is, for example, Al, Ag or Mg. The alloy material is, for example, a Mg:Ag alloy or a Al:Li alloy. For example, the cathode includes a Mg:Ag alloy, where a ratio of a Mg element to an aluminum element may be in a range of 3:7 to 1:9, inclusive.

In some examples, the display panel 100 is a top-emission display panel 100. A dimension of the second electrode in the first direction X may be in a range of 10 nm to 20 nm, inclusive. The transmittance of the second electrode CE for light with a wavelength of 530 nm may be greater than or equal to 50%, such as 50%, 55%, 60% or 65%.

In some other examples, the display panel 100 is a bottom-emission display panel 100. A dimension of the second electrode CE in the first direction may be greater than or equal to 80 nm, such as 80 nm, 85 nm, 90 nm or 95 nm. In this way, it may be ensured that the second electrode CE has a good reflectivity for light as a reflective electrode.

As shown in FIGS. 9 and 10, the second electrodes CE include a second electrode CE1 located in the first sub-pixel area P1, a second electrode CE2 located in the second sub-pixel area P2, and a second electrode CE3 located in the third sub-pixel area P3.

The at least two light-emitting units 200 between the first electrode and the second electrode may be stacked in the first direction X. The number of the light-emitting units 200 between the first electrode and the second electrode CE may be two, three, or other numbers, and is not limited here.

As shown in FIG. 10, in some examples, a first light-emitting unit 210 and a second light-emitting unit 220 are included between the first electrode AE and the second electrode CE, that is, two light-emitting units 200 are included between the first electrode AE and the second electrode CE. The first light-emitting unit 210 may be in direct contact with the first electrode AE, the second light-emitting unit 220 is located between the first light-emitting unit 210 and the second electrode CE, and the second light-emitting unit 220 may be in direct contact with the second electrode CE.

The first light-emitting unit 210 includes a first light-emitting layer EML1, a first transport layer TL1 and a second transport layer TL2. The first transport layer TL1 is located between the first light-emitting layer EML1 and the first electrode AE. It can be understood that a dimension of the first transport layer TL1 in the first direction X is equal to a distance between the first electrode AE and the first light-emitting layer EML1 in the first direction. The first transport layer TL1 is configured to transport holes from the first electrode AE to the first light-emitting layer EML1. The second transport layer TL2 is located between the first light-emitting layer EML1 and the second light-emitting unit 220. It can be understood that a dimension of the second transport layer TL2 in the first direction X is equal to a distance between the first light-emitting layer EML1 and a surface of the second transport layer TL2 proximate to the second light-emitting unit 220 in the first direction X. The second transport layer TL2 is configured to transport electrons to the first light-emitting layer EML1. In this way, holes and electrons are recombined in the first light-emitting layer EML1, so that the first light-emitting layer EML1 emits light.

The second light-emitting unit 220 includes a second light-emitting layer EML2, a third transport layer TL3 and a fourth transport layer TL4. The third transport layer TL3 is located between the second light-emitting layer EML2 and the first light-emitting unit 210. It can be understood that a dimension of the third transport layer TL3 in the first direction X is equal to a distance between a surface of the third transport layer TL3 proximate to the first light-emitting unit 210 and the second light-emitting layer EML2 in the first direction X. The third transport layer TL3 is configured to transport holes to the second light-emitting layer EML2. The fourth transport layer TL4 is located between the second light-emitting layer EML2 and the second electrode CE. It can be understood that a dimension of the fourth transport layer TL4 in the first direction X is equal to a distance between the second light-emitting layer EML2 and the second electrode CE in the first direction X. The fourth transport layer TL4 is configured to transport electrons from the second electrode CE to the second light-emitting layer EML2. In this way, holes and electrons are recombined in the second light-emitting layer EML2, so that the second light-emitting layer EML2 emits light.

As shown in FIG. 10, in some embodiments, the light-emitting device further includes a charge generation layer 300 located between two adjacent light-emitting units 200. For example, the charge generation layer 300 includes an N-type charge generation sub-layer 320 and a P-type charge generation sub-layer 310 that are stacked in the first direction, and the P-type charge generation sub-layer 310 is located on a side of the N-type charge generation sub-layer 320 away from the first electrode AE. The N-type charge generation sub-layer 320 may be in direct contact with the first light-emitting unit 210. For example, the N-type charge generation sub-layer 320 is in direct contact with the second transport layer TL2 to provide electrons to the first light-emitting unit 210. The P-type charge generation sub-layer 310 may be in direct contact with the second light-emitting unit 220. For example, the P-type charge generation sub-layer 320 is in direct contact with the third transport layer TL3 to provide holes to the second light-emitting unit 220.

In some examples, the second transport layer TL2 is configured to transport the electrons provided by the charge generation layer 300 to the first light-emitting layer EML1, so that the holes provided by the first electrode AE and the electrons provided by the charge generation layer 300 are recombined to emit light in the first light-emitting layer EML1. The third transport layer TL3 is configured to transport the holes provided by the charge generation layer 300 to the second light-emitting layer EML2, so that the holes provided by the charge generation layer 300 and the electrons provided by the second electrode CE are recombined to emit light in the second light-emitting layer EML2.

The charge generation layer 300 may include metal, a non-doped organic substance, an organic PN junction composed of P-type and N-type dopants, or metal oxide, which is not limited here.

In some embodiments, in a same light-emitting device, an absolute value of a difference between a wavelength of light emitted by the first light-emitting layer EML1 and a wavelength of light emitted by the second light-emitting layer EML2 may be less than or equal to 10 nm, such as 10 nm, 8 nm, 5 nm or 3 nm.

It can be understood that two light-emitting units 200 in the same light-emitting device emit the same or similar light. In this way, the concentration of the spectral superposition of the two light-emitting units 200 may be improved, and color purity of the light and the light extraction efficiency may be improved.

For example, the light-emitting device is a blue light-emitting device. The wavelength of the light emitted by the first light-emitting layer EML1 in the blue light-emitting device is 460 nm, and the wavelength of the light emitted by the second light-emitting layer EML2 in the blue light-emitting device may be in a range of 450 nm to 470 nm. In this way, the light extraction efficiency of the light-emitting device for the light corresponding to the wavebands with overlapping wavelengths may be improved.

In some embodiments, in the same light-emitting device, a ratio of a difference between the wavelength of the light at the spectral peak emitted by the first emitting layer EML1 and the wavelength of the light at the spectral peak emitted by the second emitting layer EML2 to either of the two is less than 5%.

It can be understood that the wavelengths at the spectral peaks of two kinds of light emitted by the two light-emitting units 200 in the same light-emitting device are the same or similar. In this way, the concentration of the spectral superposition of the two light-emitting units 200 may be improved, and color purity of the light and the light extraction efficiency may be improved.

For example, the light-emitting device is a red light-emitting device. The wavelength at the spectrum peak of the light emitted by the first light-emitting layer EML1 in the red light-emitting device is 530 nm, and the wavelength at the spectrum peak of the light emitted by the second light-emitting layer EML2 in the red light-emitting device is in a range of 504 nm to 557 nm. In this way, the light extraction efficiency of the light-emitting device for the light corresponding to the wavebands with overlapping wavelengths may be improved.

As shown in FIG. 10, in some examples, the first transport layer TL1 may include a first hole injection layer HIL1 and a first hole transport layer HTL1. The first hole injection layer HIL1 is located between the first electrode AE and the first hole transport layer HTL1. The first hole injection layer HIL1 is configured to inject holes of the first electrode AE into the first hole transport layer HTL1. The first hole transport layer HTL1 is located between the first hole injection layer HIL1 and the first light-emitting layer EML1. The first hole transport layer HTL1 is configured to transport holes injected by the first hole injection layer HIL1 to the first light-emitting layer EML1, so as to cause the holes to recombine with electrons in the first light-emitting layer EML1, thereby realizing the light emission of the first light-emitting layer EML1.

In some examples, the first hole injection layer HIL1 may include a third host material and a P-type doped material. The third host material may include poly(3,4-ethylenedioxythiophene)-poly(styrenesulfonate) (PEDOT:PSS), polythiophene, polyaniline, polypyrrole, copper phthalocyanine, and 4,4′,4″ tri (N, N phenyl 3 basic blue) triphenylamine (m-MTDATA). The P-type doped material may be one of quinone derivatives or radialene compounds, but is not limited thereto. Non-limiting examples of P-type dopants are quinone derivatives, such as 7,7,8,8-Tetracyanoquinodimethane (TCNQ), 2,3,5,6-Tetrafluoro-7,7,8,8-tetracyanoquinodimethane (F4-TCNQ), or 4,4″,4″ ((1E,1″E, 1″E)cyclopropane1,2,3triylidenetris (cyanomethylylidene))tris(2,3,5,6-tetrafluorobenzonitrile).

In some embodiments, a ratio of the P-type doped material to the third host material is in a range of 1% to 6%, such as 1%, 2%, 3%, 4%, 5% or 6%. In this way, the hole injection efficiency of the first hole injection layer HIL1 may be improved by controlling the ratio of the P-type doped material to the third host material, thereby increasing the amount of holes transported to the first light-emitting layer EML1, and further increasing the amount of recombination of excitons in the first light-emitting layer EML1. Thus, the luminous efficiency of the first light-emitting layer EML1 may be improved.

In some embodiments, the P-type charge generation sub-layer 310 includes a second host material and a P-type doped material. The second host material may include metal or a non-doped organic substance. A ratio of the P-type doped material to the second host material is in a range of 1% to 6%, inclusive, such as 1%, 2%, 3%, 4%, 5% or 6%.

In this way, the difficulty of the P-type charge generation sub-layer 310 transporting holes may be reduced, so that the holes may be injected into a film layer (such as the second hole injection layer HIL2) adjacent to the P-type charge generation sub-layer 310. That is, the amount of holes moving through the P-type charge generation sub-layer 310 to the second electrode CE increases, so that the amount of holes in the second light-emitting layer EML2 increases, and thus the amount of recombination of excitons in the second light-emitting layer EML2 increases, thereby improving the luminous efficiency of the second light-emitting layer EML2.

In some examples, a ratio of the P-type doped material to the second host material is greater than a ratio of the P-type doped material to the third host material. With such provision, the luminous efficiency of the first light-emitting layer EML1 and the second light-emitting layer EML2 in the tandem OLED may be improved.

For example, a difference between the ratio of the P-type doped material to the second host material and the ratio of the P-type doped material to the third host material is in a range of 0.8% to 5%, inclusive, such as 0.8%, 1%, 2%, 3% or 4%. With such provision, the luminous efficiency of the first light-emitting layer EML1 and the second light-emitting layer EML2 in the tandem OLED may be improved.

As shown in FIG. 10, in some examples, the second transport layer TL2 may include a first electron transport layer ETL1 and a first electron injection layer EIL1. The first electron injection layer EIL1 is located between the first electron transport layer ETL1 and the charge generation layer 300. The first electron injection layer EIL1 is configured to inject electrons provided by the N-type charge generation sub-layer 320 into the first electron transport layer ETL1. The first electron transport layer ETL1 is located between the first electron injection layer EIL1 and the first light-emitting layer EML1. The first electron transport layer ETL1 is configured to transport electrons injected by the first electron injection layer EIL1 to the first light-emitting layer EML1, so as to cause the electrons to recombine with holes in the first light-emitting layer EML1, thereby realizing the light emission of the first light-emitting layer EML1.

As shown in FIG. 10, in some examples, the third transport layer TL3 may include a second hole injection layer HIL2 and a second hole transport layer HTL2. The second hole injection layer HIL2 is located between the charge generation layer 300 and the second hole transport layer HTL2. The second hole injection layer HIL2 is configured to inject holes of the P-type charge generation sub-layer into the second hole transport layer HTL2. The second hole transport layer HTL2 is located between the second hole injection layer HIL2 and the second light-emitting layer EML2. The second hole transport layer HTL2 is configured to transport holes injected by the second hole injection layer HIL2 to the second light-emitting layer EML2, so as to cause the holes to recombine with electrons in the second light-emitting layer EML2, thereby realizing the light emission of the second light-emitting layer EML2.

As shown in FIG. 10, in some examples, the fourth transport layer TL4 may include a second electron transport layer ETL2 and a second electron injection layer EIL2. The second electron injection layer EIL2 is located between the second electron transport layer ETL2 and the second electrode CE. The second electron injection layer EIL2 is configured to inject electrons provided by the second electrode CE into the second electron transport layer ETL2. The second electron transport layer ETL2 is located between the second electron injection layer EIL2 and the second light-emitting layer EML2. The second electron transport layer ETL2 is configured to transport electrons injected by the second electron injection layer EIL2 to the second light-emitting layer EML2, so as to cause the electrons to recombine with holes in the second light-emitting layer EML2, thereby realizing the light emission of the second light-emitting layer EML2.

As shown in FIG. 10, in some examples, the fourth transport layer TL4 may further include a hole blocking layer HBL. The hole blocking layer HBL may be located between the second electron transport layer ETL2 and the second light-emitting layer EML2, and the hole blocking layer HBL is configured to block holes in the second light-emitting layer EML2 from moving in a direction towards the second electrode CE.

In some embodiments, as shown in FIGS. 10 and 11, at least one light-emitting unit of the at least two light-emitting units further includes an exciton blocking layer. For example, in a case where the light-emitting device includes two light-emitting units 200, any light-emitting unit 200 of the two light-emitting units 200 may include an exciton blocking layer BL (BL1/BL2). For example, the first light-emitting unit 210 includes a first exciton blocking layer BL1 (e.g., shown in FIG. 10). As another example, the first light-emitting unit 210 includes a first exciton blocking layer BL1, and the second light-emitting unit 220 includes a second exciton blocking layer BL2 (e.g., shown in FIG. 11). The exciton blocking layer may be located on a side of the light-emitting layer of the light-emitting unit proximate to the first electrode.

For example, as shown in FIG. 10, the first exciton blocking layer BL1 includes a first sub-layer BL11 and a second sub-layer BL12 that are stacked each other in the first direction X. The first sub-layer BL11 may be configured to block electrons, and the second sub-layer BL12 may be configured to transport holes.

It will be noted that a positional relationship between the first sub-layer BL11 and the second sub-layer BL12 may be adjusted according to actual conditions. For example, the first sub-layer BL11 may be located between the second sub-layer BL12 and the first emitting layer EML1, or the second sub-layer BL12 may be located between the first sub-layer BL11 and the first emitting layer EML1.

In some examples, as shown in FIG. 10, the first sub-layer BL11 of the first exciton blocking layer BL1 is located between the first light-emitting layer EML1 and the second sub-layer BL12. The first sub-layer BL11 may be configured to transport holes and block electrons and excitons. The second sub-layer BL12 may be configured to transport holes.

The second light-emitting unit 220 includes an electron blocking layer EBL, and the electron blocking layer EBL is located between the second light-emitting layer EML2 and the second hole transport layer HTL2. The holes provided by the first electrode AE (e.g., the anode) may be transported in a direction from the first electrode AE to the second electrode CE. For example, after leaving the first electrode AE, the holes provided by the first electrode AE may come to the first exciton blocking layer BL1 in the first light-emitting unit 210 and may pass through the second sub-layer BL12 and the first sub-layer BL11 in turn, and then are injected into the first light-emitting layer EML1. Some of the holes injected into the first light-emitting layer EML1 may recombine with electrons in the first light-emitting layer EML1 to form excitons, so that the first light-emitting layer EML1 emits light. Some of the holes in the first light-emitting layer EML1 that do not recombine with electrons may continue to be transported toward the second light-emitting unit 220. After leaving the first light-emitting layer EML1, the holes may pass through the charge generation layer 300 and the electron blocking layer EBL in sequence and be injected into the second light-emitting layer EML2 of the second light-emitting unit 220, and may recombine with electrons in the second light-emitting layer EML2, so that the second light-emitting layer EML2 emits light.

Since there is a transmission barrier during transport of the holes, the closer to the second electrode CE, the less the amount of the holes transported. That is, the amount of transport of holes gradually decreases in a direction from the first electrode AE to the second electrode CE. It can be understood as that the amount of holes transported to the first sub-layer BL11 is less than the amount of holes transported to the second sub-layer BL12. Although the amount of transport of holes gradually decreases in the direction from the first electrode AE to the second electrode CE, the P-type charge generation sub-layer 310 may provide some holes and inject the holes into the second light-emitting layer EML2, thereby reducing the amount of loss of holes in the second light-emitting layer EML2 due to the transmission barrier to a certain extent.

The electrons provided by the second electrode CE (e.g., the cathode) may be transported in a direction from the second electrode CE to the first electrode AE. For example, after leaving the second electrode CE, the electrons provided by the second electrode CE may be injected into the second light-emitting layer EML2 in the second light-emitting unit 220 and recombine with holes in the second light-emitting layer EML2 to form excitons. The electrons in the second light-emitting layer EML2 that do not recombine with holes may continue to be transported toward the first electrode AE. Subsequently, the electrons may pass through the electron blocking layer EBL. Although the electron blocking layer EBL may block electrons, some of the electrons may still pass through the electron blocking layer EBL and be transported to the first light-emitting unit 210. In addition, the N-type charge generation sub-layer 320 may provide some electrons and inject the electrons into the first light-emitting unit 210, and thus the amount of loss of electrons in the first light-emitting layer EML1 due to the electron blocking layer EBL and the transmission barrier may be reduced.

Then, when the electrons are transported to the first light-emitting layer EML1, the first sub-layer BL11 may block excitons and electrons in the first light-emitting layer EML1, thereby causing most of the electrons moving from the first light-emitting layer EML1 to the first electrode AE to remain in the first light-emitting layer EML1.

In addition to blocking electrons in the first light-emitting layer 122, the electron blocking layer in FIG. 1 also needs to have an ability to block excitons and transport holes. Therefore, the electron blocking layer has a poor ability to block electrons. There is still significant loss of electrons in the first light-emitting layer 122, which results in few electrons remaining in the first light-emitting layer 122. In this way, there is a large difference between the number of electrons remaining in the first light-emitting layer 122 and the number of electrons remaining in the second light-emitting layer 132.

In the embodiments of the present disclosure, as shown in FIG. 10, in a case where the first exciton blocking layer BL1 is provided on a side of the first light-emitting layer EML1 proximate to the first electrode AE, the first exciton blocking layer BL1 has a stacked double-layer structure, and the first sub-layer BL11 is located between the first light-emitting layer EML1 and the second sub-layer BL12. Since the first sub-layer BL11 may mainly block electrons in the first light-emitting layer EML1, it may reduce the loss of electrons in the first light-emitting layer EML1. Therefore, the amount of electrons remaining in the first light-emitting layer EML1 may increase, and thus the amount of excitons recombined in the first light-emitting layer EML1 may increase.

In this way, the provision of the double-layer structure of the first sub-layer BL11 and the second sub-layer BL12 may enhance the performance of blocking electrons in the first light-emitting layer EML1, so as to reduce the amount of loss of electrons in the first light-emitting layer EML1. Therefore, the amount of electrons remaining in the first light-emitting layer EML1 increases, and further the amount of excitons formed by recombination of electrons and holes in the first light-emitting layer EML1 may increase. In addition, the first sub-layer BL11 may also block excitons in the first light-emitting layer EML1, so that the excitons stay in the first light-emitting layer EML1 as much as possible, and thus the amount of excitons remaining in the first light-emitting layer EML1 may further increase. As a result, the amount of excitons remaining in the first light-emitting layer EML1 and the amount of excitons remaining in the second light-emitting layer EML2 are as close as possible, thereby improving the luminous efficiency of the first light-emitting layer EML1. Therefore, the luminous efficiency of the first light-emitting layer EML1 may be as consistent as possible with the luminous efficiency of the second light-emitting layer EML2.

In some examples, as shown in FIG. 11, the light-emitting device includes two light-emitting units 200, and the two light-emitting units 200 each include an exciton blocking layer BL. For example, the first light-emitting unit 210 includes a first exciton blocking layer BL1, and the second light-emitting unit 220 includes a second exciton blocking layer BL2.

As shown in FIG. 11, in the first direction X, the light-emitting device includes a first electrode AE, a first exciton blocking layer BL1, a first light-emitting layer EML1, a charge generation layer 300, a second exciton blocking layer BL2, a second light-emitting layer EML2 and a second electrode CE in sequence.

The holes provided by the first electrode AE, after leaving the first electrode AE, may come to the first exciton blocking layer BL1 and may pass through the second sub-layer BL12 and the first sub-layer BL11 in turn, and then are injected into the first light-emitting layer EML1. Some of the holes injected into the first light-emitting layer EML1 may recombine with electrons in the first light-emitting layer EML1 to form excitons, so that the first light-emitting layer EML1 emits light. Holes in the first light-emitting layer EML1 that do not recombine with electrons may continue to be transported toward the second electrode CE. After leaving the first light-emitting layer EML1, the holes may pass through the charge generation layer 300 and the second exciton blocking layer BL2 in sequence and then be injected into the second light-emitting layer EML2, so that the second light-emitting layer EML2 emits light. Similarly, there is a transmission barrier during transport of the holes, and the amount of holes transported to the second light-emitting layer EML2 may be reduced. However, the P-type charge generation sub-layer 310 may provide some holes and inject the holes into the second light-emitting layer EML2, thereby reducing the amount of loss of holes in the second light-emitting layer EML2 due to the transmission barrier to a certain extent.

After leaving the second electrode CE, the electrons provided by the second electrode CE may be injected into the second light-emitting layer EML2 in the second light-emitting unit 220 and recombine with holes in the second light-emitting layer EML2 to form excitons. The electrons in the second light-emitting layer EML2 that do not recombine with holes may continue to be transported toward the first electrode AE. Subsequently, the electrons may pass through the first sub-layer BL21 and the second sub-layer BL22 of the second exciton blocking layer BL2. Since the first sub-layer BL21 of the second exciton blocking layer BL2 has a good ability to block electrons, most electrons may be blocked in the second light-emitting layer EML2, and some electrons may pass through the first sub-layer BL21 and the second sub-layer BL22 of the second exciton blocking layer BL2 and continue to be transported toward the first electrode AE. After leaving the second light-emitting layer EML2, the electrons may pass through the charge generation layer 300 and then be injected into the first light-emitting layer EML1, so that the first light-emitting layer EML1 emits light.

There is a transmission barrier during transport of the electrons, and the amount of electrons transported to the first light-emitting layer EML1 may be reduced. However, the N-type charge generation sub-layer 320 may provide some electrons and inject the electrons into the first light-emitting layer EML1, thereby reducing the amount of loss of electrons in the first light-emitting layer EML1 due to the transmission barrier to a certain extent.

Then, when the electrons are transported to the first light-emitting layer EML1, the first sub-layer BL11 of the first exciton blocking layer BL1 may block excitons and electrons in the first light-emitting layer EML1, thereby causing most of the electrons moving from the first light-emitting layer EML1 to the first electrode AE to remain in the first light-emitting layer EML1.

In FIG. 1, in a case where the first electron blocking layer 121 is provided on a side of the first light-emitting layer 122 proximate to the first electrode 110, and the second electron blocking layer 131 is also provided on a side of the second light-emitting layer 132 proximate to the first electrode 110, since the electron blocking layer with a single-layer structure has a poor ability to block electrons, there are still significant loss of electrons in the first light-emitting layer 122, resulting in few electrons remaining in the first light-emitting layer 122. There is a large difference between the number of electrons remaining in the first light-emitting layer 122 and the number of electrons remaining in the second light-emitting layer 132.

In the embodiments of the present disclosure, as shown in FIG. 11, the first exciton blocking layer BL1 is provided on a side of the first light-emitting layer EML1 proximate to the first electrode AE, the second exciton blocking layer BL2 is provided on a side of the second light-emitting layer EML2 proximate to the first electrode AE, and the above exciton blocking layers both have a double-layer structure. Thus, it may enhance the performance of each light-emitting unit in blocking electrons. In this way, by reducing the amount of loss of electrons in each light-emitting unit, the amount of recombined excitons in each light-emitting unit may increase, thereby improving the luminous efficiency of each light-emitting unit and realizing improvement of the luminous efficiency of the overall light-emitting device.

As shown in FIGS. 10 and 11, in some examples, a thickness of the first sub-layer of the exciton blocking layer (e.g., BL1 or BL2) may be less than a thickness of the second sub-layer of the exciton blocking layer (e.g., BL1 or BL2). For example, in the first direction X, the thickness of the first sub-layer BL11 of the first exciton blocking layer BL1 may be less than the thickness of the second sub-layer BL12 of the first exciton blocking layer BL1. The thickness of the first sub-layer BL11 may be in a range of 4 nm to 25 nm, inclusive; and the thickness of the second sub-layer BL12 may be in a range of 20 nm to 50 nm, inclusive.

For example, the thickness of the second sub-layer BL12 is at most 6 times the thickness of the first sub-layer BL11. That is, a ratio of the thickness of the second sub-layer BL12 to the thickness of the first sub-layer BL11 is in a range of 1 to 6, inclusive, such as 1, 2, 3, 4, 5 or 6.

As shown in FIGS. 10 and 11, in some examples, in the same exciton blocking layer (e.g., BL1 or BL2), the highest occupied molecular orbital (HOMO) energy level of the first sub-layer is higher than the highest occupied molecular orbital energy level of the second sub-layer.

It is easy for holes to transition from a film layer with a low HOMO energy level to a film layer with a high HOMO energy level, but it is not easy for holes to transition from a film layer with a high HOMO energy level to a film layer with a low HOMO energy level. Therefore, the HOMO energy level of the first sub-layer is higher than the HOMO energy level of the second sub-layer, so that the difficulty of the holes transitioning from the second sub-layer to the first sub-layer may be reduced, thereby improving the hole transport rate. As a result, more holes may successfully transition to the first sub-layer, thereby increasing the amount of holes transported to the first sub-layer.

For example, an absolute value of a difference between the highest occupied molecular orbital energy level of the first sub-layer and the highest occupied molecular orbital energy level of the second sub-layer is less than 1 eV, such as 0 eV, 0.1 eV, 0.2 eV, 0.4 eV, 0.6 eV, 0.8 eV or 1 eV.

In some embodiments, in the same exciton blocking layer (e.g., BL1 or BL2), the first sub-layer is further configured to transport holes. The hole mobility of the first sub-layer may be greater than the hole mobility of the second sub-layer. Alternatively, the hole mobility of the first sub-layer may be equal to the hole mobility of the second sub-layer. Alternatively, the hole mobility of the first sub-layer may be less than the hole mobility of the second sub-layer.

In some examples, in the same exciton blocking layer (e.g., BL1 or BL2), the hole mobility of the first sub-layer is less than the hole mobility of the second sub-layer. Such a provision may improve the hole mobility of a side of the light-emitting layer proximate to the first electrode.

For example, under the same electric field intensity, for the first exciton blocking layer BL1, the hole mobility of the second sub-layer BL12 is at most 100 times the hole mobility of the first sub-layer BL11. That is, a ratio of the hole mobility of the second sub-layer BL12 to the hole mobility of the first sub-layer BL11 is in a range of 1 to 100, inclusive, such as 1, 2, 3, 4 . . . 98, 99, 100.

It can be understood that a ratio of the hole mobility of the first sub-layer BL11 to the hole mobility of the second sub-layer BL12 may be flexibly adjusted according to the actual needs of the light-emitting device, so as to meet the requirements of the light-emitting unit for the hole mobility of the exciton blocking layer.

In a case where each light-emitting unit 200 of the light-emitting device includes an exciton blocking layer, the exciton blocking layers BL in different light-emitting units 200 may have the same or different hole mobility, which is not limited here.

As shown in FIG. 11, in some embodiments, the hole mobility of the first sub-layer BL11 of the first exciton blocking layer BL1 in the first light-emitting unit 210 may be greater than or less than or equal to the hole mobility of the first sub-layer BL21 of the second exciton blocking layer BL2 in the second light-emitting unit 220.

For example, the hole mobility of the first sub-layer BL11 of the first exciton blocking layer BL1 in the first light-emitting unit 210 is less than or equal to the hole mobility of the first sub-layer BL21 of the second exciton blocking layer BL2 in the second light-emitting unit 220. In this way, the first sub-layer BL11 of the first exciton blocking layer BL1 may increase the difficulty of holes transported to the first light-emitting layer EML1, thereby reducing the amount of holes transported to the first light-emitting layer EML1, and further reducing the amount of excitons generated by recombination of holes in the first light-emitting layer EML1. In addition, the first sub-layer BL21 of the second exciton blocking layer BL2 may decrease the difficulty of holes transported to the second light-emitting layer EML2, thereby increasing the amount of holes transported to the second light-emitting layer EML2, and further increasing the amount of excitons generated by recombination of holes in the second light-emitting layer EML2. In this way, it is convenient to make the amount of holes recombined with electrons in the second light-emitting layer EML2 close to the amount of holes recombined with electrons in the first light-emitting layer EML1, so that an exciton recombination area of the first light-emitting layer EML1 and an exciton recombination area of the second light-emitting layer EML2 are as close as possible, thereby improving the luminous efficiency of the light-emitting device.

For example, the hole mobility of the first sub-layer BL21 of the second exciton blocking layer BL2 in the second light-emitting unit 210 is at most 100 times the hole mobility of the first sub-layer BL11 of the first exciton blocking layer BL1 in the first light-emitting unit 220. That is, a ratio of the hole mobility of the first sub-layer BL21 of the second exciton blocking layer BL2 to the hole mobility of the first sub-layer BL11 of the first exciton blocking layer BL1 is in a range of 1 to 100, inclusive. For example, under the same electric field intensity, the hole mobility of the first sub-layer BL21 of the second exciton blocking layer BL2 in the second light-emitting unit 220 may be 1.5×10⁻⁴ cm²/(V·s), and the hole mobility of the first sub-layer BL11 of the first exciton blocking layer BL1 in the first light-emitting unit 210 may be 9.9×10⁻⁶ cm²/(V·s).

As shown in FIG. 11, in some embodiments, the hole mobility of the second sub-layer BL12 of the first exciton blocking layer BL1 in the first light-emitting unit 210 may be greater than or less than or equal to the hole mobility of the second sub-layer BL22 of the second exciton blocking layer BL2 in the second light-emitting unit 220.

For example, in a case where the hole mobility of the second sub-layer BL12 of the first exciton blocking layer BL1 in the first light-emitting unit 210 is less than or equal to the hole mobility of the second sub-layer BL22 of the second exciton blocking layer BL2 in the second light-emitting unit 220, the second sub-layer BL12 of the first exciton blocking layer BL1 may increase the difficulty of holes transported to the first light-emitting layer EML1, thereby reducing the amount of holes transported to the first light-emitting layer EML1, and the second sub-layer BL22 of the second exciton blocking layer BL2 may decrease the difficulty of holes transported to the second light-emitting layer EML2, thereby increasing the amount of holes transported to the second light-emitting layer EML2. In addition, the charge generation layer 300 may provide some holes to the second light-emitting layer EML2. In this way, it is convenient to adjust the amounts of holes corresponding to the second light-emitting layer EML2 and the first light-emitting layer EML1, so that the amounts of holes of the two are as close as possible, thereby improving the luminous efficiency of the light-emitting device.

For example, the hole mobility of the second sub-layer BL22 of the second exciton blocking layer BL2 in the second light-emitting unit 220 is at most 100 times the hole mobility of the second sub-layer BL12 of the first exciton blocking layer BL1 in the first light-emitting unit 210. That is, a ratio of the hole mobility of the second sub-layer BL22 of the second exciton blocking layer BL2 to the hole mobility of the second sub-layer BL12 of the first exciton blocking layer BL1 is in a range of 1 to 100, inclusive.

For example, under the same electric field intensity, the hole mobility of the second sub-layer BL22 of the second exciton blocking layer BL2 in the second light-emitting unit 220 may be 8.2×10⁻⁴ cm²/(V·s), and the hole mobility of the second sub-layer BL12 of the first exciton blocking layer BL1 in the first light-emitting unit 210 may be 5.4×10⁻⁵ cm²/(V·s).

As shown in FIG. 11, in some embodiments, triplet state energies respectively configured for the first sub-layer BL11 and the second sub-layer BL12 of the first exciton blocking layer BL1 may be different.

In some examples, a triplet state energy configured for the first sub-layer BL11 may be greater than a triplet state energy configured for the second sub-layer BL12. For example, a difference between the triplet state energy configured for the first sub-layer BL11 and the triplet state energy configured for the second sub-layer BL12 may be less than or equal to 0.5 eV, such as 0.01 eV, 0.08 eV, 0.15 eV, 0.18 eV, . . . 0.3 eV, 0.4 eV or 0.5 eV.

In some examples, the triplet state energy of the first sub-layer BL11 may be 2.54 eV, the triplet state energy of the second sub-layer BL12 may be 2.48 eV, and a difference between the triplet state energy configured for the first sub-layer BL11 and the triplet state energy configured for the second sub-layer BL12 may be 0.06 eV.

As shown in FIG. 11, in some embodiments, triplet state energies respectively configured for the first sub-layer BL21 and the second sub-layer BL22 of the second exciton blocking layer BL2 may also be different.

In some examples, a triplet state energy configured for the first sub-layer BL21 may be greater than a triplet state energy configured for the second sub-layer BL22. For example, a difference between the triplet state energy configured for the first sub-layer BL21 and the triplet state energy configured for the second sub-layer BL22 may be less than or equal to 0.5 eV, such as 0.01 eV, 0.08 eV, 0.15 eV, 0.18 eV, . . . 0.3 eV, 0.4 eV or 0.5 eV.

In some examples, the triplet state energy of the first sub-layer BL21 may be 2.52 eV, the triplet state energy of the second sub-layer BL22 may be 2.45 eV, and the difference between the triplet state energy configured for the first sub-layer BL21 and the triplet state energy configured for the second sub-layer BL22 may be 0.07 eV.

The embodiments of the present disclosure provide four materials for comparison. The parameters corresponding to the four materials are seen for detailed in Table 1

TABLE 1

| | | | Triplet state | |
|---|---|---|---|---|
| Name | HOMO | LUMO | energy | Hole mobility |
| Material A | 5.39 | 2.37 | 2.48 | 5.4 × 10⁻⁵ |
| Material B | 5.52 | 2.52 | 2.54 | 9.9 × 10⁻⁶ |
| Material C | 5.32 | 2.22 | 2.45 | 8.2 × 10⁻⁴ |
| Material D | 5.48 | 2.42 | 2.52 | 1.5 × 10⁻⁴ |

LUMO in Table 1 represents the lowest unoccupied molecular orbital energy level, and the hole mobility is the hole mobility corresponding to each material under the electric field of 5000 N/C.

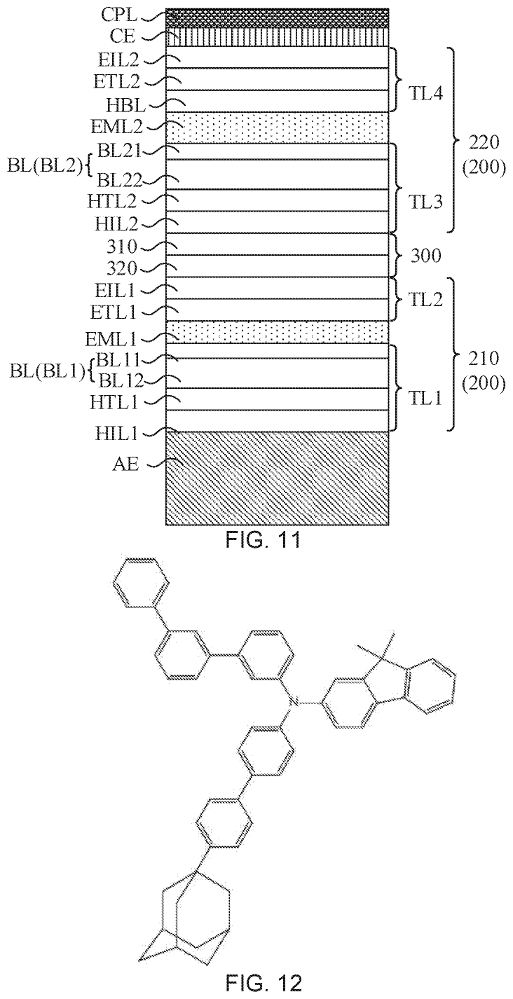

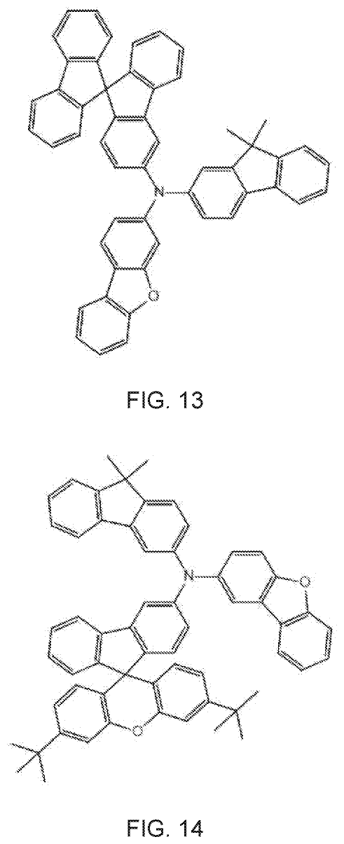

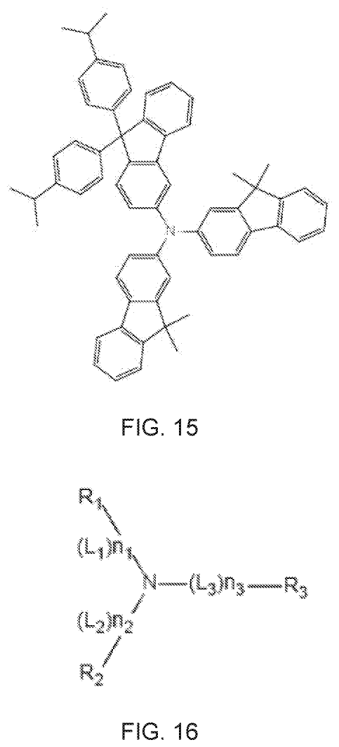

The molecular structural formula of the material A may refer to FIG. 12, the molecular structural formula of the material B may refer to FIG. 13, the molecular structural formula of the material C may refer to FIG. 14, and the molecular structural formula of the material D may refer to FIG. 15. The molecular structural formulas of the materials A to D all satisfy a general formula 1. The structure of the general formula 1 may refer to FIG. 16.

L₁, L₂ and Lain FIG. 16 may be benzene or biphenyl, where n₁, n₂ and n₃ may each be 0 or 1. In a case where n₁, n₂ and n₃ are all 0, N (nitrogen atom) and R substituents are directly connected. In a case where n₁, n₂ and n₃ are all 1, N is connected to the R substituents through L₁ to L₃. In addition, n₁, n₂ and n₃ may not be equal. For example, in a case where n₁ is 0, it corresponds to the above connection relationship between R₁ and N in the case where n₁, n₂ and n₃ are all 0; and in a case where n₁ is 1, it corresponds to the above connection relationship between R₁ and N in the case where n₁, n₂ and n₃ are all 1.

The above R₁, R₂ and R₃ may be any of benzene, biphenyl, naphthalene, adamantane, diphenylene oxide, dibenzothiophene, dimethylfluorene, diphenylfluorene, spirofluorene or spiroxanthene. In a case where R₁, R₂ and R₃ each undergo a substitution reaction, substituents of the R₁, R₂ and R₃ may be deuterium atoms, alkyl groups containing 1 to 4 C or benzene.

The exciton blocking layer BL may be formed by using any one or more of the materials A to D. For example, the material B is used to form the first sub-layer, and the material A is used to form the second sub-layer.

In some embodiments, the light-emitting layer corresponding to each light-emitting unit may have the same material. For example, the first light-emitting layer EML1 may include a first host material and a luminescent material. The second light-emitting layer EML2 may also include the first host material and the luminescent material. The first host material may be a wide bandgap material, and the wide bandgap material may be a compound including at least one group of carbazolyl group, carboline group, spirofluorenyl group, fluorenyl group, silicon group, and phosphineoxy group. The luminescent material may be a phosphorescent material and a fluorescent material, such as a green luminescent material and a red luminescent material.

In some embodiments, a ratio of the luminescent material to the first host material is in a range of 4% to 15%, inclusive. For example, the luminescent material may be a phosphorescent material, the first host material may be a wide bandgap material, and a ratio of the phosphorescent material to the wide bandgap material is in a range of 4% to 15%, inclusive, such as 4%, 5%, 6%, 7%, 8%, 9%, 10%, 11%, 12%, 13%, 14% or 15%. The first host material is doped with the luminescent material, and the ratio of the luminescent material to the first host material may be adjusted, thereby improving the luminous efficiency of the light-emitting layer.

In some embodiments, a ratio of the first host material to the luminescent material in the first light-emitting layer EML1 may be different from a ratio of the first host material to the luminescent material in the second light-emitting layer EML2.

A ratio of the luminescent material of the second light-emitting layer EML2 to the first host material of the second light-emitting layer EML2 may be greater than or less than or equal to a ratio of the luminescent material of the first light-emitting layer EML1 to the first host material of the first light-emitting layer EML1.

In some examples, the ratio of the luminescent material of the second light-emitting layer EML2 to the first host material of the second light-emitting layer EML2 is greater than the ratio of the luminescent material of the first light-emitting layer EML1 to the first host material of the first light-emitting layer EML1.

For example, the ratio of the luminescent material of the second light-emitting layer EML2 to the first host material of the second light-emitting layer EML2 is at most 3 times the ratio of the luminescent material of the first light-emitting layer EML1 to the first host material of the first light-emitting layer EML1. That is, a ratio of the ratio of the luminescent material of the second light-emitting layer EML2 to the first host material of the second light-emitting layer EML2 to the ratio of the luminescent material of the first light-emitting layer EML1 to the first host material of the first light-emitting layer EML1 is in a range of 1 to 3, inclusive, such as 1, 2 or 3. Such a provision may improve the life of the light-emitting device.

As shown in FIG. 3, the light extraction layer CPL covers the light-emitting device layer LDL. For example, the light extraction layer CPL is directly located on the second electrode CE. The light extraction layer CPL may improve the light extraction efficiency of the light-emitting device layer LDL. The light extraction layer CPL has a large refractive index and a small light absorption coefficient.

In some examples, a dimension of the light extraction layer CPL in the first direction X may be in a range of 50 nm to 80 nm, inclusive. The refractive index of the light extraction layer CPL for light with a wavelength of 460 nm may be greater than or equal to 1.8, such as 1.8, 1.9, 2.0 or 2.1, which is not limited here.

As shown in FIG. 9, the encapsulation layer TFE is used to encapsulate the light-emitting device layer LDL and the light extraction layer CPL. In some embodiments, the encapsulation layer TFE may include a first encapsulation layer ENL1, a second encapsulation layer ENL2 and a third encapsulation layer ENL3 that are stacked. For example, the first encapsulation layer ENL1 and the third encapsulation layer ENL3 are each made of inorganic material(s), and the inorganic material(s) are selected from at least one of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON) or lithium fluoride. As another example, the second encapsulation layer ENL2 is made of organic material(s), and the organic material(s) are selected from at least one of acrylic resin, methacrylic resin, polyisoprene, vinyl resin, epoxy resin, polyurethane resin, cellulose resin or perylene resin. The number of layers, the material and the structure of the thin film encapsulation layer TFE may be varied by those skilled in the art according to requirements, and are not limited thereto in the present disclosure.

The embodiments of the present disclosure provide 7 groups of schemes for comparison. The structure of the light-emitting device is as shown in FIG. 11. The parameters of the 7 groups of schemes are seen for detailed in Table 2.

TABLE 2

| | | | | | GD ratio | GD ratio | PD ratio | PD ratio |
|---|---|---|---|---|---|---|---|---|
| Name | BL12 | BL11 | BL22 | BL21 | (EML1) | (EML2) | (HIL) | (P-CGL) |
| Scheme 1 | A, 100 Å | B, 20 Å | C, 100 Å | D, 20 Å | 10% | 8% | 2% | 4% |
| Scheme 2 | A, 60 Å | B, 60 Å | C, 60 Å | D, 60 Å | 10% | 8% | 2% | 4% |
| Scheme 3 | C, 100 Å | D, 20 Å | A, 100 Å | B, 20 Å | 10% | 8% | 2% | 4% |
| Scheme 4 | B, 120 Å | | D, 120 Å | | 10% | 8% | 2% | 4% |
| Scheme 5 | A, 40 Å | B, 80 Å | C, 40 Å | D, 80 Å | 10% | 8% | 2% | 4% |
| Scheme 6 | A, 100 Å | B, 20 Å | C, 100 Å | D, 20 Å | 10% | 10% | 2% | 4% |
| Scheme 7 | A, 100 Å | B, 20 Å | C, 100 Å | D, 20 Å | 10% | 8% | 2% | 2% |

In Table 2, the GD ratio (EML1) is a ratio of the luminescent material of the first light-emitting layer EML1 to the first host material of the first light-emitting layer EML1; the GD ratio (EML2) is a ratio of the luminescent material of the second light-emitting layer EML2 to the first host material of the second light-emitting layer EML2; the PD ratio (HIL) is a ratio of the P-type doped material to the third host material; and the PD ratio (P-CGL) is a ratio of the P-type doped material to the second host material.

Table 3 shows voltages, efficiencies, color coordinates X, color coordinates Y and lives corresponding to the 7 groups of schemes in Table 2.

TABLE 3

| | | | Color | Color | |
|---|---|---|---|---|---|
| | | Luminous | coordinate | coordinate | |
| Name | Voltage | efficiency | X | Y | Life |
| Scheme 1 | 100% | 100% | 0.245 | 0.723 | 100% |
| Scheme 2 | 104% | 101% | 0.245 | 0.723 | 108% |
| Scheme 3 | 101% | 89% | 0.245 | 0.723 | 92% |
| Scheme 4 | 111% | 94% | 0.245 | 0.723 | 98% |
| Scheme 5 | 97% | 95% | 0.245 | 0.723 | 102% |
| Scheme 6 | 105% | 97% | 0.245 | 0.723 | 106% |
| Scheme 7 | 104% | 94% | 0.245 | 0.723 | 94% |

It can be seen from Table 2 that in the schemes 1 to 7, the exciton blocking layer in the scheme 4 has a single-layer structure, and the exciton blocking layers in the other schemes all have double-layer structures.

It can be seen from the scheme 1, the scheme 2 and the scheme 4 that under the same other conditions, a light-emitting device provided with an exciton blocking layer with a single-layer structure requires a higher driving voltage, while a light-emitting device provided with an exciton blocking layer with a double-layer structure requires a lower driving voltage. Therefore, it can be concluded that the exciton blocking layer with the double-layer structure may reduce the driving voltage of the light-emitting device compared with the exciton blocking layer with the single-layer structure.

Similarly, it can be seen from the scheme 1, the scheme 2 and the scheme 4 that under the same other conditions, the luminous efficiency of the light-emitting device provided with the exciton blocking layer with the single-layer structure is lower than the luminous efficiency of the light-emitting device provided with the exciton blocking layer with the double-layer structure. Therefore, it can be concluded that the exciton blocking layer with the double-layer structure may improve the luminous efficiency of the light-emitting device compared with the exciton blocking layer with the single-layer structure.

Similarly, it can be seen from the scheme 1, the scheme 2 and the scheme 4 that under the same other conditions, the life of the light-emitting device provided with the exciton blocking layer with the single-layer structure is lower than the life of the light-emitting device provided with the exciton blocking layer with the double-layer structure. Therefore, it can be concluded that the exciton blocking layer with the double-layer structure may improve the life of the light-emitting device compared with the exciton blocking layer with the single-layer structure.

In the scheme 1, the first sub-layer of the first exciton blocking layer is made of the material B, the second sub-layer of the first exciton blocking layer is made of the material A, the first sub-layer of the second exciton blocking layer is made of the material D, and the second sub-layer of the second exciton blocking layer is made of the material C. In the scheme 3, the first sub-layer of the first exciton blocking layer is made of the material D, the second sub-layer of the first exciton blocking layer is made of the material C, the first sub-layer of the second exciton blocking layer is made of the material B, and the second sub-layer of the second exciton blocking layer is made of the material A. It can be understood in combination with Table 1 as that in the scheme 1, the first exciton blocking layer is formed by using a material with a low hole mobility, and the second exciton blocking layer is formed by using a material with a high hole mobility; and in the scheme 3, the first exciton blocking layer is formed by using the material with the high hole mobility, and the second exciton blocking layer is formed by using the material with the low hole mobility. It can be seen from Table 3 that, the luminous efficiency and the life in the scheme 1 are better than the luminous efficiency and the life in the scheme 3. That is, under the same other conditions, in a case where the hole mobility of the first exciton blocking layer of the first light-emitting unit is lower than the hole mobility of the second exciton blocking layer of the first light-emitting unit, and the hole mobility of the first exciton blocking layer of the second light-emitting unit is higher than the hole mobility of the second exciton blocking layer of the second light-emitting unit, the luminous efficiency and the life of the first light-emitting unit are better than the luminous efficiency and the life of the second light-emitting unit. Therefore, it can be obtained that the luminous efficiency and the life of a light-emitting device having a first exciton blocking layer with a low hole mobility and a second exciton blocking layer with a high hole mobility are better than the luminous efficiency and the life of a light-emitting device having a first exciton blocking layer with a high hole mobility and a second exciton blocking layer with a low hole mobility.

It can be seen according to the sequence of the scheme 1, the scheme 2 and the scheme 5 that the thicknesses of the first sub-layers gradually increase and the thicknesses of the second sub-layers gradually decrease. Under the same other conditions, the luminous efficiencies of the light-emitting devices first increase and then decrease. In a case where the thickness of the first sub-layer and the thickness of the second sub-layer are equal, the luminous efficiency of the light-emitting device reaches a high value. Therefore, it can be obtained that in the case where the thickness of the first sub-layer and the thickness of the second sub-layer are equal, the light-emitting device has a good luminous efficiency.

It can be seen according to the sequence of the scheme 1, the scheme 2 and the scheme 5 that the thicknesses of the first sub-layers gradually increase and the thicknesses of the second sub-layers gradually decrease. Under the same other conditions, the lives of the light-emitting devices first increase and then decrease. In a case where the thickness of the first sub-layer and the thickness of the second sub-layer are equal, the life of the light-emitting device reaches a high value. Therefore, it can be obtained that in the case where the thickness of the first sub-layer and the thickness of the second sub-layer are equal, the light-emitting device has a long life.

It can be seen from the scheme 1 and the scheme 6 that under the same other conditions, as the ratios of the luminescent materials in the second light-emitting layers EML2 to the first host materials in the second light-emitting layers EML2 decrease, the driving voltages and the lives of the light-emitting devices gradually decrease, and the luminous efficiencies of the light-emitting devices gradually increase. It can be obtained that the driving voltages and the lives of the light-emitting devices gradually decrease as the ratios of the luminescent materials in the second light-emitting layers EML2 to the first host materials in the second light-emitting layers decrease, and the luminous efficiencies of the light-emitting devices gradually increase as the ratios of the luminescent materials in the second light-emitting layers EML2 to the first host materials in the second light-emitting layers decrease.

It can be seen from the scheme 1 and the scheme 7 that under the same other conditions, as the ratios of the P-type doped materials in the P-type charge generation sub-layers to the second host materials in the P-type charge generation sub-layers increase, the driving voltages of the light-emitting devices gradually decrease, and the luminous efficiencies and the lives of the light-emitting devices gradually increase. It can be obtained that the driving voltages of the light-emitting devices gradually decrease as the ratios of the P-type doped materials in the P-type charge generation sub-layers to the second host materials in the P-type charge generation sub-layers increase, and the luminous efficiencies and the lives of the light-emitting devices gradually increase as the ratios of the P-type doped materials in the P-type charge generation sub-layers to the second host materials in the P-type charge generation sub-layers increase.

In summary, in the light-emitting device provided by the embodiments of the present disclosure, the exciton blocking layer BL in the light-emitting unit is provided with a double-layer structure in which the first sub-layer and the second sub-layer are stacked, so that the property of the exciton blocking layer blocking electrons may be improved, and it may facilitate that an exciton recombination area of the first light-emitting layer EML1 and an exciton recombination area of the second light-emitting layer EML2 are as close as possible, thereby improving the luminous efficiency of the light-emitting device. In addition, a low-voltage driving of the light-emitting device may be achieved and the service life of the light-emitting device may be prolonged.

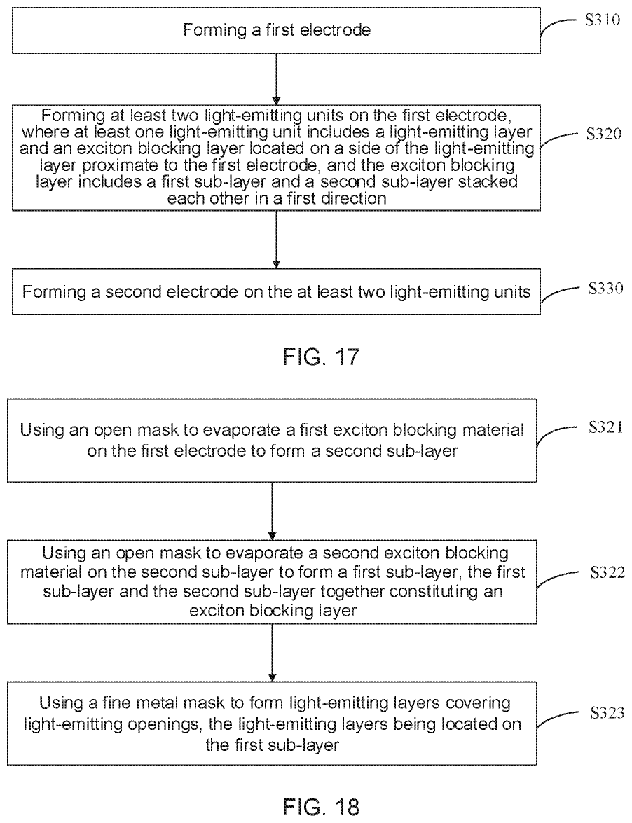

Referring to FIG. 17, the present disclosure further provides a method for manufacturing a light-emitting device. The manufacturing method includes steps S310 to S330.

In step S310, a first electrode is formed.

As shown in FIG. 9, before step S310, the manufacturing method may further include providing a substrate SUB. A material of the substrate SUB may be, for example, polyethylene terephthalate (PET), polyimide (PI), or cyclo olefin polymer (COP).

The substrate SUB may include first sub-pixel areas P1, second sub-pixel areas P2 and third sub-pixel areas P3. The first sub-pixel areas P1, the second sub-pixel areas P2 and the third sub-pixel areas P3 have been described above in detail, and are not repeated here.

A pixel circuit layer is formed on the substrate SUB. The pixel circuit layer includes a plurality of pixel circuits. The plurality of pixel circuits have been described above in detail, and are not repeated here.

After the plurality of pixel circuits are formed, an insulating layer INL covering the plurality of pixel circuits is formed.

In some examples, as shown in FIG. 9, the first electrode AE may be an anode, and the anode may be formed on the insulating layer INL through a patterning process. The anode may be made of a material of a metal or combination of Ag, Mg, Al, Pt, Pd, Au, Ni, Nd, Ir or Cr, or may be made of a conductive metal oxide material such as ITO, IZO or IGZO.

In some examples, the anode may include a laminated composite structure of transparent conductive oxide/metal/transparent conductive oxide. The material of the transparent conductive oxide is, for example, ITO or IZO, and the material of the metal is, for example, Au, Ag, Ni or Pt. For example, the anode has a structure of ITO/Ag/ITO. The anodes may include a first anode, a second anode and a third anode. The first anode is located in the first sub-pixel area P1, the second anode is located in the second sub-pixel area P2, and the third anode is located in the third sub-pixel area P3.

Before step S320, a pixel defining layer may further be formed on the anode. The pixel defining layer is provided with a plurality of light-emitting openings therein, and the light-emitting openings expose the first electrodes.

The pixel defining layer PDL may be formed on the insulating layer and the anodes. For example, a pixel defining material layer covering the insulating layer and the anodes is formed by deposition, and part of the pixel defining material layer is removed by etching to obtain the pixel defining layer PDL. The pixel defining layer PDL includes a first light-emitting opening K1 covering the first sub-pixel area P1, a second light-emitting opening K2 covering the second sub-pixel area P2, and a third light-emitting opening K3 covering the third sub-pixel area P3.

The first light-emitting opening K1 exposes the first anode, the second light-emitting opening K2 exposes the second anode, and the third light-emitting opening K3 exposes the third anode.

In step S320, at least two light-emitting units are formed on the first electrode. At least one of the light-emitting units includes a light-emitting layer and an exciton blocking layer located on a side of the light-emitting layer proximate to the first electrode. The exciton blocking layer includes a first sub-layer and a second sub-layer stacked each other in a first direction.

As shown in FIGS. 3, 9 and 10, in some embodiments, the same light-emitting device may include a first light-emitting unit and a second light-emitting unit, and the first light-emitting unit and the second light-emitting unit are sequentially formed in the first direction X.

In some examples, as shown in FIG. 10, the first light-emitting unit may include a first hole injection layer HIL1, a first hole transport layer HTL1, a first exciton blocking layer BL1, a first light-emitting layer EML1 and a second transport layer TL2.

A hole injection material is evaporated on the pixel definition layer PDL and the first electrode in each light-emitting opening using an open mask, so as to form the first hole injection layer HIL1.

A hole transport material is evaporated on the first hole injection layer HIL1 using an open mask, so as to form the first hole transport layer HTL1. The hole transport material may use a carbazole material with a high hole mobility.

The first exciton blocking layer covering the first hole transport layer HTL1 is formed. The first exciton blocking layer includes a first sub-layer and a second sub-layer, and both the first sub-layer and the second sub-layer may be films covering the first light-emitting openings K1, the second light-emitting openings K2, the third light-emitting openings K3 and the non-light-emitting area P4 between adjacent openings.

In some examples, as shown in FIGS. 3, 9 and 10, a second sub-layer BL12 covering the first light-emitting opening K1, the second light-emitting opening K2, the third light-emitting opening K3 and the non-emitting region P4 between adjacent openings is formed on the first hole transport layer HTL1.

A first sub-layer BL11 the first light-emitting opening K1, the second light-emitting opening K2, the third light-emitting opening K3 and the non-emitting region P4 between adjacent openings is formed on the second sub-layer BL12.

In some examples, positions of the first sub-layer and the second sub-layer may be exchanged. That is, the first sub-layer may be formed and then the second sub-layer is formed.

For example, the first sub-layer covering the first light-emitting opening K1, the second light-emitting opening K2, the third light-emitting opening K3 and the non-light-emitting area P4 between adjacent openings may be formed on the first hole transport layer HTL1.

The second sub-layer covering the first light-emitting opening K1, the second light-emitting opening K2, the third light-emitting opening K3 and the non-light-emitting area P4 between adjacent openings is formed on the first sub-layer.

After the first exciton blocking layer is formed, a first light-emitting layer EML1 covering the first light-emitting opening K1, a first light-emitting layer EML1 covering the second light-emitting opening K2, and a first light-emitting layer EML1 covering the third light-emitting opening K3 may be formed on the first exciton blocking layer. First light-emitting layers EML1 in two adjacent light-emitting openings are independent of each other.

After the first light-emitting layers are formed, a second transport layer TL2 covering the first light-emitting layers and the first exciton blocking layer is formed. The second transport layer TL2 may also cover the pixel defining layer PDL, and part of the second transport layer TL2 covering the pixel defining layer PDL and part of the second transport layer TL2 covering the light-emitting openings form a continuous film.

In some examples, the second transport layer TL2 includes a first electron transport layer ETL1 and a first electron injection layer EIL1. As shown in FIGS. 3, 9 and 10, the step of forming the second transport layer may include the following contents.

An electron transport material is evaporated on the first light-emitting layers EML1 using an open mask, so as to form the first electron transport layer ETL1 covering the first light-emitting layers and the first exciton blocking layer. The electron transport material may use a triazine material with a high electron mobility. A dimension of the first electron transport layer ETL1 in the first direction X may be in a range of 5 nm to 50 nm, inclusive.

An electron injection material is evaporated on the first electron transport layer ETL1 using an open mask, so as to form the first electron injection layer EIL1. A dimension of the first electron injection layer EIL1 in the first direction X may be in a range of 0.5 nm to 20 nm, inclusive.

In some examples, after the first light-emitting unit 210 is formed, the method may further include forming a charge generation layer 300. The charge generation layer 300 may cover the first light-emitting opening K1, the second light-emitting opening K2, the third light-emitting opening K3, and the pixel defining layer PDL. That is, the charge generation layer 300 covers the second transport layer TL2.

In some examples, the second light-emitting unit 220 includes a third transport layer TL3, a second light-emitting layer, and a fourth transport layer TL4. Forming the second light-emitting unit 220 may include the following contents.

The third transport layer TL3 covering the charge generation layer 300 is formed. The third transport layer TL3 may cover the first light-emitting opening K1, the second light-emitting opening K2, the third light-emitting opening K3 and the pixel defining layer PDL, and part of the third transport layer TL3 covering the pixel defining layer PDL and the part of the third transport layer TL3 covering the light-emitting openings form a continuous film.

In some examples, as shown in FIGS. 3, 9 and 11, the third transport layer TL3 includes a second hole injection layer HIL2, a second hole transport layer HTL2 and a second exciton blocking layer BL2. Forming the third transport layer TL3 may include the following contents.

A hole injection material is evaporated on the charge generation layer 300 using an open mask, so as to form the second hole injection layer HIL2. The second hole injection layer HIL2 may have the same structural features as the first hole injection layer HIL1, which is not repeated here.

A hole transport material is evaporated on the second hole injection layer HIL2 using an open mask, so as to form the second hole transport layer HTL2. The second hole transport layer HTL2 may have the same structural features as the first hole transport layer HTL1, which is not repeated here.

The second exciton blocking layer BL2 covering the second hole transport layer HTL2 is formed on the second hole transport layer HTL2 using an open mask. The structure of the second exciton blocking layer BL2 may be a double-layer structure that is the same as the structure of the first exciton blocking layer BL1. The structure of the second exciton blocking layer BL2 may alternatively be a single-layer structure that is different from the structure of the first exciton blocking layer BL1.

A second light-emitting layer covering the first light-emitting opening K1, a second light-emitting layer covering the second light-emitting opening K2, and a second light-emitting layer covering the third light-emitting opening K3 are formed on the third transport layer TL3. Second light-emitting layers in two adjacent light-emitting openings are independent of each other.

The fourth transport layer TL4 covering the second light-emitting layer covering the first light-emitting opening K1, the second light-emitting layer covering the second light-emitting opening K2, and the second light-emitting layer covering the third light-emitting opening K3 is formed. The fourth transport layer TL4 may also cover the pixel defining layer PDL, and part of the fourth transport layer TL4 covering the pixel defining layer PDL and part of the fourth transport layer TL4 covering the light-emitting openings form a continuous film.

In some examples, the fourth transport layer TL4 includes a hole blocking layer HBL, a second electron transport layer ETL2, and a second electron injection layer EIL2. As shown in FIGS. 3, 9 and 11, the step of forming the fourth transport layer TL4 may include the following contents.

A third exciton blocking material is evaporated on the second exciton blocking layer BL2 and the second light-emitting layer in each light-emitting opening using an open mask, so as to form the hole blocking layer HBL.

An electron transport material is evaporated on the hole blocking layer HBL using an open mask, so as to form the second electron transport layer ETL2. The second electron transport layer ETL2 may have the same structural features as the first electron transport layer ETL1, which is not repeated here.

An electron injection material is evaporated on the second electron transport layer ETL2 using an open mask, so as to form the second electron injection layer EIL2. The second electron injection layer EIL2 may have the same structural features as the first electron injection layer EIL1, which is not repeated here.

In step S330, a second electrode is formed on the at least two light-emitting units.

The second electrode covering the fourth transport layer TL4 is formed. The second electrode may cover the first light-emitting opening K1, the second light-emitting opening K2, the third light-emitting opening K3 and the pixel defining layer PDL, and part of the second electrode covering the pixel defining layer PDL and part of the second electrode covering the light-emitting openings form a continuous film.

The second electrode CE may be a cathode, and the cathode may have semi-transmissive or transmissive properties. In some embodiments, the cathode may be made of one or a compound or a mixture of Ag, Mg, Cu, Al, Pt, Pd, Au, Ni, Nd, Ir, Cr, Li, Ca, LiF/Ca, LiF/AI, Mo or Ti, such as a mixture of Ag and Mg.

In some examples, after step S330, the method may further include forming a light extraction layer CPL on a side of the second electrode away from the substrate SUB.

The exciton blocking layer in the light-emitting device obtained by using the method for manufacturing the light-emitting device provided in the present embodiments has a stacked structure including the first sub-layer and the second sub-layer, so that the ability of the exciton blocking layer blocking electrons and blocking excitons may be improved, and it may facilitate that an exciton recombination area of the first light-emitting layer and an exciton recombination area of the second light-emitting layer EML2 are as close as possible, thereby improving the luminous efficiency of the light-emitting device.

In some embodiments, as shown in FIG. 18, forming a light-emitting unit on the first electrode in step S320 includes steps S321 to S323. The steps S321 to S323 may be used to form the first light-emitting unit or to form the second light-emitting unit, which is not limited here.

In step S321, a first exciton blocking material is evaporated on the first electrode using an open mask to form a second sub-layer.

In some examples, the steps S321 to S323 may be used to form the first light-emitting unit. As shown in FIGS. 3, 9 and 10, the step S321 may include: using the open mask to evaporate the first exciton blocking material on the first hole transport layer HTL1, so as to form the second sub-layer BL12 covering the first light-emitting opening K1, the second light-emitting opening K2, the third light-emitting opening K3 and the non-light-emitting area P4 between adjacent openings.

In some examples, the steps S321 to S323 may be used to form the second light-emitting unit. As shown in FIGS. 3, 9 and 11, the step S321 may include: using the open mask to evaporate the first exciton blocking material on the second hole transport layer HTL2, so as to form the second sub-layer BL22 covering the first light-emitting opening K1, the second light-emitting opening K2, the third light-emitting opening K3 and the non-light-emitting area P4 between adjacent openings.

In step S322, a second exciton blocking material is evaporated on the second sub-layer using an open mask to form a first sub-layer. The first sub-layer and the second sub-layer together constitute the exciton blocking layer.

In some examples, the steps S321 to S323 may be used to form the first light-emitting unit. As shown in FIGS. 3, 9 and 10, the step S322 may include: using the open mask to evaporate the second exciton blocking material on the second sub-layer BL12, so as to form the first sub-layer BL11 covering the first light-emitting opening K1, the second light-emitting opening K2, the third light-emitting opening K3 and the non-light-emitting area P4 between adjacent openings.

In some examples, the steps S321 to S323 may be used to form the second light-emitting unit. As shown in FIGS. 3, 9 and 11, the step S322 may include: using the open mask to evaporate the second exciton blocking material on the second sub-layer BL22, so as to form the first sub-layer BL21 covering the first light-emitting opening K1, the second light-emitting opening K2, the third light-emitting opening K3 and the non-light-emitting area P4 between adjacent openings.

In step S323, a fine metal mask is used to form light-emitting layers covering the light-emitting openings, and the light-emitting layers are located on the first sub-layer.

In some examples, the steps S321 to S323 may be used to form the first light-emitting unit. As shown in FIGS. 3, 9 and 10, the fine metal mask (FMM) is used to evaporate first luminescent materials of different colors on portions of the exciton blocking layer in different light-emitting openings, so as to form the first light-emitting layers EML1. For example, the fine metal mask is used to evaporate a first red luminescent material on the first sub-layer BL11 in the first light-emitting opening K1 to form a first light-emitting layer EML1 covering the first light-emitting opening K1; and then the fine metal mask is used to evaporate a first green luminescent material on the first sub-layer BL11 in the second light-emitting opening K2 to form a first light-emitting layer EML1 covering the second light-emitting opening K2.

In some examples, the steps S321 to S323 may be used to form the second light-emitting unit. As shown in FIGS. 3, 9 and 11, the fine metal mask is used to evaporate second luminescent materials of different colors on portions of the first sub-layer BL21 in different light-emitting openings, so as to form the second light-emitting layers EML2. For example, the fine metal mask is used to evaporate a second red luminescent material on the first sub-layer BL21 in the first light-emitting opening K1 to form a second light-emitting layer EML2 covering the first light-emitting opening K1;

and then the fine metal mask is used to evaporate a second green luminescent material on the first sub-layer BL21 in the second light-emitting opening K2 to form a second light-emitting layer EML2 covering the second light-emitting opening K2.

The first red luminescent material and the second red luminescent material may be the same material or different materials; similarly, the first green luminescent material and the second green luminescent material may be the same material or different materials, which is not limited here.

In the present embodiments, an open mask may be used to obtain common layer(s) each connecting and covering all the light-emitting openings, such as the exciton blocking layer BL, the second transport layer TL2, the third transport layer TL3, and the fourth transport layer TL4; and a fine metal mask may form the first light-emitting layer and the second light-emitting layer each covering all the light-emitting openings, thereby improving the position accuracy of the first light-emitting layer and the second light-emitting layer, and improving the manufacturing efficiency of the light-emitting devices.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode, at least two light-emitting units and a second electrode sequentially stacked in a first direction, wherein
the at least two light-emitting units include a first light-emitting unit and a second light-emitting unit, and the second light-emitting unit is located between the first light-emitting unit and the second electrode;
at least one light-emitting unit of the at least two light-emitting units includes a light-emitting layer and an exciton blocking layer located on a side of the light-emitting layer proximate to the first electrode; the exciton blocking layer includes a first sub-layer and a second sub-layer stacked on each other in the first direction, and the first sub-layer is located between the second sub-layer and the light-emitting layer; and
in the first direction, a thickness of the first sub-layer is less than a thickness of the second sub-layer, and a highest occupied molecular orbital energy level of the first sub-layer is higher than a highest occupied molecular orbital energy level of the second sub-layer.

2. The light-emitting device according to claim 1, wherein the thickness of the second sub-layer is at most 6 times the thickness of the first sub-layer.

3. The light-emitting device according to claim 1, wherein an absolute value of a difference between the highest occupied molecular orbital energy level of the first sub-layer and the highest occupied molecular orbital energy level of the second sub-layer is less than 1 eV.

4. The light-emitting according to claim 1, wherein a hole mobility of the first sub-layer is less than a hole mobility of the second sub-layer.

5. The light-emitting device according to claim 4, wherein the hole mobility of the second sub-layer is at most 100 times the hole mobility of the first sub-layer.

6. The light-emitting device according to claim 1, wherein the light-emitting layer includes a first host material and a luminescent material, and a ratio of the luminescent material to the first host material is in a range of 4% to 15%, inclusive.

7. The light-emitting device according to claim 1, wherein the first light-emitting unit includes a first light-emitting layer, the second light-emitting unit includes a second light-emitting layer, and both the first light-emitting unit and the second light-emitting unit include exciton blocking layers.

8. The light-emitting device according to claim 7, wherein a ratio of a luminescent material of the second light-emitting layer to a first host material of the second light-emitting layer is greater than a ratio of a luminescent material of the first light-emitting layer to a first host material of the first light-emitting layer.

9. The light-emitting device according to claim 7, wherein a ratio of a luminescent material of the second light-emitting layer to a first host material of the second light-emitting layer is at most 3 times a ratio of a luminescent material of the first light-emitting layer to a first host material of the first light-emitting layer.

10. The light-emitting device according to claim 7, wherein a hole mobility of a first sub-layer of an exciton blocking layer of the first light-emitting unit is less than or equal to a hole mobility of a first sub-layer of an exciton blocking layer of the second light-emitting unit.

11. The light-emitting device according to claim 10, wherein the hole mobility of the first sub-layer of the exciton blocking layer of the second light-emitting unit is at most 100 times the hole mobility of the first sub-layer of the exciton blocking layer of the first light-emitting unit.

12. The light-emitting device according to claim 1, further comprising a charge generation layer, wherein the charge generation layer is located between the first light-emitting unit and the second light-emitting unit.

13. The light-emitting device according to claim 12, wherein the charge generation layer includes an N-type charge generation sub-layer and a P-type charge generation sub-layer stacked in the first direction, the P-type charge generation sub-layer is located on a side of the N-type charge generation sub-layer away from the first electrode; the P-type charge generation sub-layer includes a second host material and a P-type doped material, and a ratio of the P-type doped material to the second host material is in a range of 1% to 6%, inclusive.

14. The light-emitting device according to claim 13, wherein the first light-emitting unit includes an exciton blocking layer; the first light-emitting unit further includes a hole injection layer, the hole injection layer is located on a side of a second sub-layer in the first light-emitting unit proximate to the first electrode; the hole injection layer includes a third host material and a P-type doped material, and a ratio of the P-type doped material to the third host material is in a range of 1% to 6%, inclusive.

15. The light-emitting device according to claim 14, wherein the ratio of the P-type doped material in the P-type charge generation sub-layer to the second host material is greater than the ratio of the P-type doped material in the hole injection layer to the third host material.

16. The light-emitting device according to claim 15, wherein a difference between the ratio of the P-type doped material in the P-type charge generation sub-layer to the second host material and the ratio of the P-type doped material in the hole injection layer to the third host material is in a range of 0.8% to 5%, inclusive.

17. A display panel, comprising:
a pixel defining layer provided with a plurality of light-emitting openings therein; and
a plurality of light-emitting devices, the plurality of light-emitting devices covering the plurality of light-emitting openings, respectively, and at least one light-emitting device being the light-emitting device according to claim 1.

18. A method for manufacturing a light-emitting device, comprising:
forming a first electrode;
forming at least two light-emitting units on the first electrode, wherein at least one light-emitting unit includes a light-emitting layer and an exciton blocking layer located on a side of the light-emitting layer proximate to the first electrode; and the exciton blocking layer includes a first sub-layer and a second sub-layer stacked on each other in a first direction; and
forming a second electrode on the at least two light-emitting units.

19. The method according to claim 18, wherein forming a light-emitting unit on the first electrode, includes:
using an open mask to evaporate a first exciton blocking material on the first electrode to form a second sub-layer;
using the open mask to evaporate a second exciton blocking material on the second sub-layer to form a first sub-layer, the first sub-layer and the second sub-layer together constituting an exciton blocking material layer; and
using a fine metal mask to form a light-emitting layer covering a light-emitting opening, the light-emitting layer being located on the first sub-layer.
